(19) United States
(12) Patent Application Publication
(10) Pub. No.: US 2025/0002782 A1
(43) Pub. Date: Jan. 2, 2025

(54) OXIDE FLUORESCENT MATERIAL AND LIGHT EMITTING DEVICE USING THE SAME

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 18/754,365

(22) Filed: Jun. 26, 2024

(30) Foreign Application Priority Data
Jun. 27, 2023 (JP) 2023-105244

(51) Int. Cl. C09K 11/68; C01B 33/32; C01G 17/00; C01G 37/14; H01L 33/50

(52) U.S. Cl. CPC C09K 11/684; C01B 33/32; C01G 17/006; C01G 37/14; C09K 11/682; C09K 11/685; H01L 33/502; C01P 2002/54; C01P 2006/60

(57) ABSTRACT

An oxide fluorescent material has a composition represented by the following formula (1):

(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p≤1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2.

### CROSS-REFERENCE TO RELATED PATENT APPLICATION

This application claims priority to Japanese Patent Application No. 2023-105244, filed on Jun. 27, 2023, the disclosure of which is hereby incorporated by reference in its entirety.

### BACKGROUND

### Technical Field

The present disclosure relates to an oxide fluorescent material and a light emitting device using the same.

### Description of Related Art

Light emitting devices having light emission intensity in a wavelength range from red light to near-infrared light are desired for use in, for example, infrared cameras, infrared communication, light sources for plant growth and cultivation, vein authentication, which is a type of biometric authentication, food component analyzers for non-destructive measurement of sugar content and other parameters in agricultural products or foods such as fruits and vegetables, and analyzers for non-destructive measurement of foreign substances in pharmaceutical products. Light emitting devices that emit light in the wavelength range from red light to near-infrared light as well as in a wavelength range of visible light are also desired.

Examples of such light emitting devices include a light emitting device in which a light emitting diode (LED) and a fluorescent material are combined.

Examples of the fluorescent material to be combined in the light emitting device include a fluorescent material having a light emission spectrum with a relatively large light emission intensity in the wavelength range from red light to near-infrared light (hereinafter, also referred to as “near-infrared light emitting fluorescent material”).

As the near-infrared light emitting fluorescent material, Japanese Translation of PCT International Application Publication No. 2020-528486 discloses a fluorescent material having a light emission peak wavelength of 680 nm or more and 760 nm or less and having a composition represented by, for example, CaYAlO₄:Mn⁴⁺. Near-infrared light emitting fluorescent materials with a light emission spectrum in a wavelength range having a wider full width at half maximum and a longer light emission peak wavelength, which are suitable for each application described above, may be required.

### SUMMARY

The present disclosure has an object to provide an oxide fluorescent material having a light emission spectrum with a light emission peak wavelength in a wavelength range from red light to near-infrared light and with a wider full width at half maximum, and a light emitting device using the same.

A first aspect of the present disclosure relates to an oxide fluorescent material having a composition represented by the following formula (1).

(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p≤1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2.

A second aspect of the present disclosure relates to a light emitting device including the oxide fluorescent material and a light emitting element having a light emission peak wavelength that is 365 nm or more and 650 nm or less and irradiating the oxide fluorescent material.

The present disclosure provides an oxide fluorescent material having a light emission spectrum with a light emission peak wavelength in a wavelength range from red light to near-infrared light and with a wider full width at half maximum, and a light emitting device using the same.

### BRIEF DESCRIPTION OF THE DRAWINGS

FIG. 1 is a schematic cross-sectional view showing an exemplary light emitting device according to a first embodiment of the present disclosure.

FIG. 2 is a schematic cross-sectional view showing another exemplary light emitting device according to the first embodiment of the present disclosure.

FIG. 3A is a schematic plan view showing an exemplary light emitting device according to a second embodiment of the present disclosure.

FIG. 3B is a schematic cross-sectional view showing an exemplary light emitting device according to the second embodiment of the present disclosure.

FIG. 4 is a graph showing light emission spectra of the oxide fluorescent materials according to Examples 1 to 6.

FIG. 5 is a graph showing light emission spectra of the oxide fluorescent materials according to Examples 7 to 11.

FIG. 6 is a graph showing light emission spectra of the oxide fluorescent materials according to Examples 12 to 16.

FIG. 7 is a graph showing a light emission spectrum of the oxide fluorescent material according to Comparative Example 1.

### DETAILED DESCRIPTION

The oxide fluorescent material according to the present disclosure, the light emitting device using the same, and the method for producing an oxide fluorescent material are described below. The embodiments described below are intended to embody the technical idea of the present disclosure, and the present disclosure is not limited to the following oxide fluorescent material and the light emitting device. For visible light, the relationship between color names and chromaticity coordinates, and the relationship between wavelength ranges of light and color names of monochromatic light are in accordance with Japanese Industrial Standard (JIS) Z8110. In this specification, the “fluorescent material” is used in the same meaning as a “fluorescent phosphor”.

Light emitting devices using a fluorescent material are required to emit light in an appropriate wavelength range according to a visual object and conditions of use. For example, in the medical field, there may be a need to easily obtain information inside a living body. The living body includes light absorbers such as water, hemoglobin, and melanin. For example, hemoglobin has a high light absorptance in a visible light wavelength range of less than 650 nm, and with a light emitting device that emits light in the visible light wavelength range, the light in the visible light wavelength range is less easily transmitted through the living body, which makes it difficult to obtain information inside the living body. If it is possible to irradiate light in a wavelength range where absorption and scattering of light in living tissues are reduced, it becomes easier to obtain information deep inside the living body. Therefore, there is a need for a light emitting device that can emit light in a wavelength range referred to as a “biological window” where light easily transmits through the living body. The “biological window” may be referred to as a “first biological window” in a wavelength range from around 650 nm to 950 nm, may be referred to as a “second biological window” in a wavelength range from around 1,000 nm to 1,350 nm, and may be referred to as a “third biological window” in a wavelength range from around 1,500 nm to 1,800 nm. For example, if the increase or decrease of oxygen concentration in the blood in the living body can be measured by measuring the increase or decrease of light absorption due to hemoglobin that binds to oxygen, the information inside the living body can be easily obtained by irradiation with the light emitted from the light emitting device. If the information deep inside the living body can be obtained by irradiation with the light emitted from the fluorescent material and the light emitting element instead of irradiating X-rays or others, it is possible to obtain the information inside the living body more safely. Therefore, the fluorescent material used in the light emitting device may be required to have a light emission peak wavelength in a wavelength range from red light to near-infrared light. The fluorescent material used in the light emitting device may be required to have a light emission peak wavelength of 680 nm or more and 1,000 nm or less, or a light emission peak wavelength of 840 nm or more and 970 nm or less. Recently, there is a need for a light emitting device that emits light in a wavelength range from red light to near-infrared light, which allows for more clearly visualizing deep inside the living body and is highly safe. When a light emitting device including a light emitting element and a fluorescent material is configured to allow a high current to flow into the light emitting device and can emit light with high output power, detection capability can be improved, making it easier to obtain information inside the living body.

In the agricultural and food fields, there is a need for non-destructive sugar content meters for non-destructively measuring the sugar content of agricultural products and fruits and vegetables, and non-destructive taste meters for rice. Near-infrared spectroscopy may be used as a non-destructive method for measuring internal quality such as sugar content, acidity, ripeness, and internal damage of fruits and vegetables, and the outer-layer quality appearing on the skin surface of fruits and vegetables or in the outer layer near the skin surface, such as abnormal drying. In the near-infrared spectroscopy, fruits and vegetables are irradiated with light in the near-infrared light wavelength range, and the transmitted light that is transmitted through the fruits and vegetables and the reflected light that is reflected by the fruits and vegetables are received, and the quality of the fruits and vegetables is measured by measuring the decrease in light intensity (light absorption). Light sources such as tungsten or xenon lamps are used in near-infrared spectroscopy analysis devices used in such food fields. The general rules for near-infrared spectrophotometric analysis in JIS K0134 state that near-infrared rays have a wavelength range of 700 nm or more and 2,500 nm or less.

In the face of environmental changes such as climate change, it is also desirable to stably supply plants such as vegetables and to increase the production efficiency of plants. Plant factories that can be artificially controlled can stably supply safe vegetables to the market, and are expected to be a next-generation industry. Such plant factories require a light emitting device that emits light capable of promoting the growth of plants. Reactions of plants to light can be grouped into photosynthesis and photomorphogenesis. Photosynthesis is a reaction that uses light energy to decompose water, generate oxygen, and fix carbon dioxide to organic materials, which is a necessary reaction for the growth of plants. Photomorphogenesis is a morphogenetic reaction that uses light as a signal for seed germination, differentiation (germ formation, leaf formation), movement (pore opening and closing, chloroplast movement), and photorefraction. In the photomorphogenesis reaction, it has been found that light with the wavelength of 690 nm or more and 800 nm or less affects the photoreceptors of plants. Therefore, light emitting devices used in plant factories may be required to be capable of emitting light in the wavelength range that affects plant photoreceptors (chlorophyll a, chlorophyll b, carotenoids, phytochromes, cryptochromes, and phototropins) and promotes the growth of plants.

For use in the light emitting device using a light emitting element such as a light emitting diode (LED) or laser diode (LD) configured to emit light in a range of purple to blue as an excitation light source, the above-mentioned near-infrared light emitting fluorescent material has room for improvement in the light emission characteristics of the fluorescent material such that the light emitting device can emit light suitable for intended use.

Light emitting devices that emit light in the red light to near-infrared light wavelength range as well as in the wavelength range of 365 nm or more and less than 700 nm may be required. For example, it may be necessary to emit light in the visible light wavelength range not only to obtain internal information on living bodies and fruits and vegetables, but also to enhance the visibility of objects.

The oxide fluorescent material has a composition represented by the following formula (1).

(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p≤1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2.

When the parameter y in the formula (1), which represents the molar ratio of the activating element Cr, is 0.002 or more and 0.5 or less (0.002≤y≤0.5) in 1 mol of the composition of the oxide fluorescent material, the oxide fluorescent material has a light emission spectrum with a light emission peak wavelength in a desired wavelength range from red light to near-infrared light depending on the purpose of use, and with a relatively wide full width at half maximum. In the oxide fluorescent material, the parameter y in the formula (1) may be 0.005 or more and 0.40 or less (0.005≤y≤0.40), may be 0.010 or more and 0.30 or less (0.010≤y≤0.30), may be 0.015 or more and 0.20 or less (0.015≤y≤0.20), may be 0.020 or more and 0.15 or less (0.020≤y≤0.15), may be 0.020 or more and 0.10 or less (0.020≤y≤0.10), may be 0.020 or more and 0.090 or less (0.020≤y≤0.090), may be 0.020 or more and 0.080 or less (0.020≤y≤0.080), or may be 0.020 or more and 0.070 or less (0.020≤y≤0.070), in 1 mol of the composition of the oxide fluorescent material. In the present specification, in the composition formulae representing the compositions of the fluorescent materials including the oxide fluorescent material, the part before the colon (:) represents elements and the molar ratio constituting a host crystal, and the part after the colon (:) represents an activating element.

In the oxide fluorescent material, the first element M¹ included as necessary may be at least one element selected from the group consisting of Ca, Sr, Ba, and Zn, or may be two or more elements selected from the group consisting of Ca, Sr, Ba, and Zn in the composition represented by the formula (1). In one example, the oxide fluorescent material does not contain the first element M¹ but contains Mg. In the oxide fluorescent material, a part of Mg may be replaced by the first element M¹, or two or more elements may be contained as the first element M¹. In the oxide fluorescent material, Mg may be entirely replaced by the first element M¹ in the composition represented by the formula (1). When the first element M¹ is Zn, Mg may be entirely replaced by Zn. In one example, the oxide fluorescent material does not contain Mg and contains Zn as an essential element, and Mg is replaced by at least one first element M¹ selected from the group consisting of Ca, Sr, and Ba, or by two or more elements may be contained as the first element M¹ in the composition represented by the formula (1).

In the oxide fluorescent material, the parameter q in the formula (1), which represents the total molar ratio of Mg and the first element M¹, is 0.1 or more and 0.9 or less (0.1≤q≤0.9) in 1 mol of the composition of the oxide fluorescent material. When the parameter q in the formula (1), which represents the total molar ratio of Mg and the first element M¹, is 0.1 or more and 0.9 or less (0.1≤q≤0.9) in 1 mol of the composition of the oxide fluorescent material, the oxide fluorescent material has a light emission spectrum with a light emission peak wavelength in a desired wavelength range from red light to near-infrared light depending on the purpose of use, and with a wider full width at half maximum. In the oxide fluorescent material, the parameter q in the formula (1), which represents the total molar ratio of Mg and the first element M¹, may be 0.2 or more and 0.9 or less (0.2≤q≤0.9), may be 0.3 or more (0.3≤q), or may be 0.4 or more (0.4≤q), in 1 mol of the composition of the oxide fluorescent material. In order to obtain an oxide fluorescent material having a stable crystal structure, the parameter q in the formula (1), which represents the total molar ratio of Mg and the first element M¹, may be 0.5 or more and 0.9 or less (0.5≤q≤0.9), or may be 0.6 or more and 0.9 or less (0.6≤q≤0.9), in 1 mol of the composition of the oxide fluorescent material.

In the oxide fluorescent material, the molar ratio of the first element M¹ included as necessary is represented by a product of the parameter q and the parameter p in the formula (1), wherein the parameter p is 0 or more and 1.0 or less (0≤p≤1.0) in 1 mol of the composition of the oxide fluorescent material. In the oxide fluorescent material, Mg may be entirely replaced by the first element M¹ in the formula (1), wherein the parameter p may be 1.0 (p=1.0), in 1 mol of the composition of the oxide fluorescent material. The oxide fluorescent material contains the first element M¹ as a part of Mg in the formula (1), wherein the parameter p in the formula (1) may be more than 0 and 1.0 or less (0<p≤1.0), may be 0 or more and less than 1.0 (0≤p<1.0), may be 0.9 or less (p≤0.9), may be 0.8 or less (p≤0.8), may be 0.7 or less (p≤0.7), may be 0.6 or less (p≤0.6), may be 0.5 or less (p≤0.5), or may be 0 or more and 0.4 or less (0≤p≤0.4), in 1 mol of the composition of the oxide fluorescent material. In order to obtain an oxide fluorescent material having a stable crystal structure, the parameter p may be 0 or more and 0.4 or less (0≤p≤0.4), when the parameter q, which represents the total molar ratio of Mg and the first element M¹, is 0.6 or more and 0.9 or less (0.6≤q≤0.9), in the composition represented by the formula (1). The oxide fluorescent material need not substantially contain the first element M¹, and the parameter p may be substantially 0 (p=0) in the composition represented by the formula (1). In the present specification, when the numerical value of the parameter representing the molar ratio of the element in the composition is “substantially 0”, it means that the element is not intentionally contained. The numerical value of the parameter representing the molar ratio of the element in the composition being substantially 0 specifically means the case where the content is 1,000 ppm by mass or less, 500 ppm by mass or less, or 1 ppm by mass or more.

In the oxide fluorescent material, the second element M² included as necessary may be at least one element selected from the group consisting of Na, K, Rb, and Cs, or may be two or more elements thereof in the composition represented by the formula (1). The oxide fluorescent material may contain part or all of Li replaced by the second element M² in the composition represented by the formula (1). Even when the oxide fluorescent material contains part or all of Li replaced by the second element M² in the composition represented by the formula (1), the oxide fluorescent material has a light emission spectrum with a light emission peak wavelength in a desired wavelength range from red light to near-infrared light depending on the purpose of use. In the oxide fluorescent material, a part of Li may be replaced by the second element M², and the second element M² may be either Na or K, in the composition represented by the formula (1). In the oxide fluorescent material, Li may be entirely replaced by the second element M², and the second element M² may be Na, in the composition represented by the formula (1).

When the parameter s in the formula (1), which represents the total molar ratio of Li and the second element M², is 0.05 or more and 0.45 or less (0.05≤s≤0.45) in 1 mol of the composition of the oxide fluorescent material, the oxide fluorescent material has a light emission spectrum with a light emission peak wavelength in a desired wavelength range from red light to near-infrared light depending on the purpose of use, and with a wider full width at half maximum. In the oxide fluorescent material, the parameter s in the formula (1) may be 0.10 or more and 0.45 or less (0.10≤s≤0.45), may be 0.15 or more and 0.45 or less (0.15≤s≤0.45), or may be 0.20 or more and 0.40 or less (0.20≤s≤0.40); and in order to obtain an oxide fluorescent material having a more stable crystal structure, the parameter s may be 0.25 or more and 0.40 or less (0.25≤s≤0.40).

In the oxide fluorescent material, it is preferred that the parameter s in the formula (1), which represents the total molar ratio of Li and the second element M², has the same value as the parameter u, which represents the total molar ratio of In and the third element M³, described below, or has a difference of 0.05 or less from the parameter u in 1 mol of the composition of the oxide fluorescent material. When the parameter s in the formula (1) has the same value as the parameter u in the formula (1), or has a difference of 0.05 or less from the parameter u in 1 mol of the composition of the oxide fluorescent material, Li and/or the second element M², which has a valence electron number of 1, easily combines with In and/or the third element M³, which has a valence electron number of 3, and the crystal structure of the oxide fluorescent material is stabilized, so that it is possible for the oxide fluorescent material to obtain a light emission spectrum with a light emission peak wavelength in a desired wavelength range from red light to near-infrared light depending on the purpose of use, and with high light emission intensity of the light emission peak wavelength. When the parameter s in the formula (1), which represents the total molar ratio of Li and the second element M², is less than 0.05 or more than 0.45 in 1 mol of the composition of the oxide fluorescent material, the parameter s is out of balance with the parameter u, which represents the total molar ratio of In and/or the third element M³ in the formula (1), and also with the parameter q, which represents the molar ratio of Mg and/or the first element M¹ in the formula (1), so that an oxide fluorescent material having a stable crystal structure cannot be obtained and no fluorescence is emitted or the light emission intensity is low even by irradiation of excitation light.

In the oxide fluorescent material, the molar ratio of the second element M² included as necessary is represented by a product of the parameter r and the parameter s in the formula (1), wherein the parameter r is 0 or more and 1.0 or less (0≤r≤1.0), in 1 mol of the composition of the oxide fluorescent material. In the oxide fluorescent material, Li may entirely be replaced by the second element M² in the formula (1), wherein the parameter r may be 1.0 (r=1.0), in 1 mol of the composition of the oxide fluorescent material. The oxide fluorescent material contains the second element M² as a part of Li in the formula (1), wherein the parameter r in the formula (1) may be more than 0 and 1.0 or less (0<r≤1.0), may be more than 0 and less than 1.0 (0<r<1.0), may be 0.1 or more and 0.9 or less (0.1≤r≤0.9), may be 0.2 or more and 0.8 or less (0.2≤r≤0.8), may be 0.3 or more and 0.7 or less (0.3≤r≤0.7), or may be 0.4 or more and 0.6 or less (0.4≤r≤0.6), in 1 mol of the composition of the oxide fluorescent material. In one example, in order to obtain a stable crystal structure, the oxide fluorescent material does not substantially contain the second element M², which is at least one element selected from the group consisting of Na, K, Rb, and Cs, each having an atomic number larger than Li, and the parameter r is substantially 0 (r=0) in the composition represented by the formula (1).

In the oxide fluorescent material, the third element M³ included as necessary may be at least one element selected from the group consisting of Al, Ga, and Sc, or may be two or more elements thereof in the composition represented by the formula (1). In the oxide fluorescent material, a part of In may be replaced by the third element M³ in the composition represented by the formula (1). In order to obtain an oxide fluorescent material having a stable crystal structure and emitting fluorescence having a light emission peak wavelength in a desired wavelength range from red light to near-infrared light, it is preferable for the oxide fluorescent material not to have all of In replaced by the third element M³, which is at least one element selected from the group consisting of Al, Ga, and Sc having an atomic number smaller than In in the composition represented by the formula (1). The oxide fluorescent material may have at least half or less of the molar ratio of In replaced by the third element M³ in the composition represented by the formula (1).

When the parameter u in the formula (1), which represents the total molar ratio of In and the third element M³, is 0.05 or more and 0.45 or less (0.05≤u≤0.45) in 1 mol of the composition of the oxide fluorescent material, the oxide fluorescent material has a light emission spectrum with a light emission peak wavelength in a desired wavelength range from red light to near-infrared light depending on the purpose of use, and with a wider full width at half maximum. In the oxide fluorescent material, the parameter u in the formula (1) may be 0.10 or more and 0.45 or less (0.10≤u≤0.45), may be 0.15 or more and 0.45 or less (0.15≤u≤0.45), or may be 0.20 or more and 0.40 or less (0.20≤u≤0.40); and in order to obtain an oxide fluorescent material having a more stable crystal structure, the parameter u may be 0.25 or more and 0.40 or less (0.25≤u≤0.40).

In the oxide fluorescent material, it is preferred that the parameter u in the formula (1), which represents the total molar ratio of In and the third element M³, has the same value as the parameter s, which represents the total molar ratio of Li and the second element M², described above, or has a difference of 0.05 or less from the parameter s in 1 mol of the composition of the oxide fluorescent material. When the parameter u in the formula (1) has the same value as the parameter s in the formula (1), or has a difference of 0.05 or less from the parameter s in 1 mol of the composition of the oxide fluorescent material, In and/or the third element M³, which has a valence electron number of 3, easily combines with Li and/or the second element M², which has a valence electron number of 1, and the crystal structure of the oxide fluorescent material is stabilized, so that it is possible for the oxide fluorescent material to obtain a light emission spectrum with a light emission peak wavelength in a desired wavelength range from red light to near-infrared light depending on the purpose of use, and with high light emission intensity of the light emission peak wavelength. When the parameter u in the formula (1), which represents the total molar ratio of In and the third element M³, is less than 0.05 or more than 0.45 in 1 mol of the composition of the oxide fluorescent material, the parameter u is out of balance with the parameter s, which represents the total molar ratio of Li and/or the second element M² in the formula (1), and also with the parameter q, which represents the molar ratio of Mg and/or the first element M¹ in the formula (1), so that an oxide fluorescent material having a stable crystal structure cannot be obtained and no fluorescence is emitted or the light emission intensity is low even by irradiation of excitation light.

In the oxide fluorescent material, the molar ratio of the third element M³ included as necessary is represented by a product of the parameter t and the parameter u in the formula (1), wherein the parameter t is 0 or more and 0.5 or less (0≤t≤0.5), in 1 mol of the composition of the oxide fluorescent material, and all of In is not be replaced by the third element M³. In order to obtain an oxide fluorescent material having a stable crystal structure, the parameter t in the formula (1) may be 0 or more and less than 0.5 (0≤t≤0.5), may be 0 or more and 0.4 or less (0≤t≤0.4), may be 0 or more and 0.3 or less (0≤t≤0.3), may be 0 or more and 0.2 or less (0≤t≤0.2), or may be 0 or more and 0.1 or less (0≤t≤0.1), in 1 mol of the composition of the oxide fluorescent material. In one example, in order to obtain a stable crystal structure, the oxide fluorescent material does not substantially contain the third element M³ that is at least one element selected from the group consisting of Al, Ga, and Sc, each having an atomic number smaller than In, and the parameter t is substantially 0 (t=0) in the composition represented by the formula (1).

In the oxide fluorescent material, the fourth element M⁴ included as necessary is at least one element selected from the group consisting of Si, Ti, Zr, Sn, and Hf in the composition represented by the formula (1). In order for the oxide fluorescent material to obtain a light emission spectrum with a light emission peak wavelength in a desired wavelength range from red light to near-infrared light depending on the purpose of use, and with a wider full width at half maximum, the fourth element M⁴ included as necessary may be either Si or Hf, or the fourth element M⁴ may be Si, in the composition represented by the formula (1).

In the oxide fluorescent material, the sum (q+s+u) of the parameter q representing the total molar ratio of Mg and the first element M¹, the parameter s representing the total molar ratio of Li and the second element M², and the parameter u representing the total molar ratio of In and the third element M³ is 0.9 or more and 1.2 or less (0.9≤q+s+u≤1.2) in 1 mol of the composition of the oxide fluorescent material. In order to obtain an oxide fluorescent material having a stable crystal structure, the sum (q+s+u) of the parameter q, the parameter s, and the parameter u may be more than 0.9 and 1.2 or less (0.9<q+s+u≤1.2), or may be 1.0 or more and 1.2 or less (1.0≤q+s+u≤1.2), in 1 mol of the composition of the oxide fluorescent material.

When the parameter w in the formula (1), which represents the total molar ratio of Ge and the fourth element M⁴, is 0.8 or more and 1.3 or less (0.8≤w≤1.3) in 1 mol of the composition of the oxide fluorescent material, the oxide fluorescent material has a light emission spectrum with a light emission peak wavelength in a desired wavelength range from red light to near-infrared light depending on the purpose of use, and with a wider full width at half maximum. In the oxide fluorescent material, the parameter w in the formula (1) may be 0.9 or more and 1.2 or less (0.9≤w≤1.2), or may be 1.0 or more and 1.2 or less (1.0≤w≤1.2). In order to obtain an oxide fluorescent material having a stable crystal structure, it is preferred that the parameter w in the formula (1), which represents the total molar ratio of Ge and the fourth element M⁴, is approximately the same as the sum (q+s+u) of the parameter q representing the total molar ratio of Mg and the first element M¹, the parameter s representing the total molar ratio of Li and the second element M², and the parameter u representing the total molar ratio of In and the third element M³. In order to obtain a stable crystal structure, the parameter w in the formula (1), which represents the total molar ratio of Ge and the fourth element M⁴, may be 1.0 (w=1.0) in the composition represented by the formula (1).

In the oxide fluorescent material, the molar ratio of the fourth element M⁴ included as necessary is represented by a product of the parameter v and the parameter w in the formula (1), wherein the parameter v is 0 or more and 1.0 or less (0≤v≤1.0), in 1 mol of the composition of the oxide fluorescent material. In the oxide fluorescent material, Ge may entirely be replaced by the fourth element M⁴ in the formula (1), wherein the parameter v may be 1.0 (v=1.0), in 1 mol of the composition of the oxide fluorescent material. The oxide fluorescent material contains the fourth element M⁴ as a part of Ge in the formula (1), wherein the parameter v in the formula (1) may be more than 0 and 1.0 or less (0<v≤1.0), or may be more than 0 and less than 1.0 (0<v<1.0), in 1 mol of the composition of the oxide fluorescent material. In one example of the oxide fluorescent material, in order to obtain an oxide fluorescent material having a stable crystal structure, Ge is not entirely replaced by the fourth element M⁴, and the parameter v in the formula (1) is 0 or more and 0.5 or less (0≤v≤0.5), 0 or more and less than 0.5 (0≤v<0.5), 0 or more and 0.4 or less (0≤v≤0.4), 0 or more and 0.3 or less (0≤v≤0.3), 0 or more and 0.2 or less (0≤v≤0.2), or 0 or more and 0.1 or less (0≤v≤0.1), in 1 mol of the composition of the oxide fluorescent material. In one example, in order to obtain a stable crystal structure, the oxide fluorescent material does not substantially contain the fourth element M⁴ that is at least one element selected from the group consisting of Si, Ti, Zr, Sn, and Hf, in which each of Si and Ti has an atomic number smaller than Ge and each of Zr, Sn, and Hf has an atomic number larger than Ge, and the parameter v may be substantially 0 (v=0), in the composition represented by the formula (1).

In order for the oxide fluorescent material to obtain a light emission spectrum with a light emission peak wavelength in a desired wavelength range from red light to near-infrared light depending on the purpose of use, and with a wider full width at half maximum, the parameter x in the formula (1), which represents the molar ratio of oxygen, may be 2.6 or more and 3.6 or less (2.6≤x≤3.6), may be 2.6 or more and 3.5 or less (2.6≤x≤3.5), may be 2.6 or more and 3.4 or less (2.6≤x≤3.4), may be 2.7 or more and 3.3 or less (2.7≤x≤3.3), may be 2.8 or more and 3.2 or less (2.8≤x≤3.2), may be 2.9 or more and 3.1 or less (2.9≤x≤3.1), or may be 3.0 (x=3.0), in 1 mol of the composition of the oxide fluorescent material.

In the oxide fluorescent material, the fifth element M⁵ included as necessary is at least one element selected from the group consisting of Ni, Ce, Eu, Fe, Mn, Nd, Tm, Ho, Er, and Yb, or may be at least one element selected from the group consisting of Ni, Ce, Eu, Fe, Mn, and Nd, in the composition represented by the formula (1).

In the oxide fluorescent material, the parameter z representing the molar ratio of the fifth element M⁵, which is the same activating element as Cr and is included as necessary, in the composition represented by the formula (1) is 0 or more and 0.3 or less (0≤z≤0.3), may be 0 or more and 0.2 or less (0≤z≤0.2), may be 0 or more and 0.1 or less (0≤z≤0.1), or may be 0.001 or more (0.001≤z), in 1 mol of the composition of the oxide fluorescent material. In one example, the oxide fluorescent material does not substantially contain the fifth element M⁵ and the parameter z is substantially 0 (z=0), in the composition represented by the formula (1).

The oxide fluorescent material preferably has a light emission spectrum with a light emission intensity at 1,000 nm of 10% or more, relative to 100% of the light emission intensity of the light emission peak wavelength, more preferably 15% or more, even more preferably 20% or more, still more preferably 30% or more, still more preferably 35% or more, and particularly preferably 37% or more. When the oxide fluorescent material has a light emission spectrum with a light emission intensity at 1,000 nm of 5% or more relative to 100% of the light emission intensity of the light emission peak wavelength, in a wavelength range of near-infrared light, the oxide fluorescent material emits light having a light emission intensity required for analysis in a wavelength range of 900 nm or more and 1,100 nm or less, which facilitates obtaining information inside living bodies or information on agricultural products, foods, and pharmaceutical products in a non-destructive manner, and it can be used in light emitting devices for analysis in place of a tungsten or xenon lamp. In the light emission spectrum of the oxide fluorescent material, the ratio of the light emission intensity at 1,000 nm to 100% of the light emission intensity of the light emission peak wavelength is preferably high. However, even when the ratio of the light emission intensity at 1,000 nm is low, if the light emission spectrum has a relatively wide full width at half maximum, it is possible for the oxide fluorescent material to emit light having a light emission intensity required for analysis for obtaining information inside living bodies or information on agricultural products, foods, and pharmaceutical products in a non-destructive manner. When the oxide fluorescent material has a light emission spectrum with a full width at half maximum that is 150 nm or more and 220 nm or less, the light emission intensity at 1,000 nm may be 10% or more relative to 100% of the light emission intensity of the light emission peak wavelength.

The oxide fluorescent material preferably has a light emission spectrum with a full width at half maximum of a light emission peak wavelength that is 150 nm or more and 220 nm or less. The oxide fluorescent material preferably converts the wavelength of excitation light emitted from an excitation light source such as a light emitting element to thereby emit light having a light emission spectrum with a light emission peak wavelength in a desired wavelength range from red light to near-infrared light, with a wider full width at half maximum, and with a light emission intensity required for analysis or other purposes.

When light having a light emission spectrum with a wider full width at half maximum can be irradiated in the wavelength range where information inside living bodies and on agricultural products can be obtained in a non-destructive manner, it is easier to obtain information inside living bodies and on agricultural products. It is also desirable for the color appearance of an object when irradiated with light (hereinafter, also referred to as “color rendering property”) to have a light emission spectrum in a wider wavelength range, and the wider the full width at half maximum, the better the color rendering property of light can be emitted. For example, when emitting light in a wavelength range that affects the growth of plants in a plant factory, it may be necessary to emit light that does not disturb the spectral balance of the light so that workers can work comfortably. The full width at half maximum of the light emission spectrum of the light emission peak wavelength in the oxide fluorescent material may be 160 nm or more, may be 165 nm or more, may be 170 nm or more, or may be 175 nm or more; and may be 215 nm or less. The full width at half maximum of the light emission spectrum of the light emission peak wavelength in the oxide fluorescent material may be 175 nm or more and 220 nm or less. In the present specification, the full width at half maximum refers to a wavelength width where the light emission intensity is 50% at the light emission peak wavelength indicating the maximum light emission intensity in the light emission spectrum.

The oxide fluorescent material preferably has a light emission spectrum with a light emission peak wavelength 830 nm or more and 930 nm or less. The oxide fluorescent material converts the wavelength of excitation light emitted from an excitation light source such as a light emitting element, and emits light in a wavelength range from red light to near-infrared light. A light emitting device including the oxide fluorescent material that emits light in the wavelength range from red light to near-infrared light can be an alternative light source to a tungsten or xenon lamp. The oxide fluorescent material preferably has a light emission spectrum in which the light emission intensity required for analysis can be obtained in a wavelength range that facilitates obtaining information inside living bodies and on agricultural products. When the oxide fluorescent material has a light emission spectrum with a light emission peak wavelength in the range of 830 nm or more and 930 nm or less, a light emission spectrum having a light emission intensity required for analysis can be obtained in a wavelength range that facilitates obtaining information inside living bodies or information on agricultural products, foods, and pharmaceutical products in a non-destructive manner. The oxide fluorescent material may have a light emission spectrum with a light emission peak wavelength of 860 nm or more and 930 nm or less, or with a light emission peak wavelength of 870 nm or more and 930 nm or less.

When the parameter q in the formula (1), which represents the total molar ratio of Mg and the first element M¹, is 0.6 or more and 0.9 or less (0.6≤q≤0.9) and the parameter p is 0 or more and 0.4 or less (0≤p≤0.4) in 1 mol of the composition of the oxide fluorescent material, an oxide fluorescent material having a stable crystal structure can be obtained, and it is preferred to have a light emission spectrum with a light emission peak wavelength in the range of 860 nm or more and 930 nm or less.

When the parameter q in the formula (1), which represents the total molar ratio of Mg and the first element M¹, is 0.5 or more and 0.9 or less (0.5≤q≤0.9) in 1 mol of the composition of the oxide fluorescent material, an oxide fluorescent material having a stable crystal structure can be obtained, and it is preferred to have a light emission spectrum with a light emission peak wavelength in the range of 860 nm or more and 930 nm or less.

When the oxide fluorescent material does not substantially contain the fourth element M⁴ in the formula (1) and the parameter v is substantially 0 (v=0) in 1 mol of the composition of the oxide fluorescent material, an oxide fluorescent material having a stable crystal structure can be obtained, and it is preferred to have a light emission spectrum with a light emission peak wavelength in the range of 870 nm or more and 930 nm or less.

The light emitting device includes an oxide fluorescent material having a composition represented by the formula (1) and a light emitting element having a light emission peak wavelength of 365 nm or more and 650 nm or less and irradiating the oxide fluorescent material. The oxide fluorescent material can be used as a member constituting a wavelength conversion member together with a light-transmissive material.

A semiconductor element can be used as the light emitting element for irradiating the oxide fluorescent material. For example, a nitride semiconductor can be selected as the material for the light emitting element that emits green or blue light. Materials such as In_{X}Al_{Y}Ga_{1-X-Y}N (0≤X≤1, 0≤Y≤1, X+Y≤1) can be used as the material for the semiconductor structure constituting the light emitting element. For example, a gallium-aluminum-arsenic semiconductor or an aluminum-indium-gallium-phosphorus semiconductor can be selected as the material for the light emitting element that emits red light. For example, an LED chip or an LD chip is preferably used for the light emitting element.

The light emitting element may have a light emission peak wavelength of 365 nm or more and 650 nm or less, may have a light emission peak wavelength of 365 nm or more and 500 nm or less, may have a light emission peak wavelength of 370 nm or more and 490 nm or less, or may have a light emission peak wavelength of 375 nm or more and 480 nm or less. The light emitting element may have a light emission peak wavelength of more than 500 nm and 650 nm or less, may have a light emission peak wavelength of 510 nm or more and 650 nm or less, or may have a light emission peak wavelength of 520 nm or more and 650 nm or less. By using the light emitting element as the excitation light source of the oxide fluorescent material, a light emitting device that emits mixed color light of light emitted from the light emitting element and fluorescence emitted from the fluorescent material containing the oxide fluorescent material in a desired wavelength range can be constituted. The full width at half maximum of the light emission peak in the light emission spectrum of the light emitting element can be, for example, 30 nm or less. For example, a light emitting element using a nitride-based semiconductor is preferably used as the light emitting element. By using a light emitting element using a nitride-based semiconductor as the excitation light source, a stable light emitting device having high efficiency, high output linearity with respect to the input, and high resistance to mechanical impacts can be obtained.

The light emitting device necessarily includes a first fluorescent material containing the oxide fluorescent material described above, and may further include a fluorescent material having a different composition. The light emitting device preferably includes, in addition to the first fluorescent material, at least one fluorescent material selected from the group consisting of a second fluorescent material having a light emission peak wavelength of 455 nm or more and less than 495 nm, a third fluorescent material having a light emission peak wavelength of 495 nm or more and less than 610 nm, a fourth fluorescent material having a light emission peak wavelength of 610 nm or more and less than 700 nm, and a fifth fluorescent material having a light emission peak wavelength of 700 nm or more and 1,050 nm or less, in the light emission spectrum of each fluorescent material. The light emitting device includes a light emitting element, a first fluorescent material containing the oxide fluorescent material described above, and at least one fluorescent material selected from the group consisting of a second fluorescent material, a third fluorescent material, a fourth fluorescent material, and a fifth fluorescent material, so that the light emitting device can be used as a light source that emits light having a light emission spectrum in a wavelength range from visible light to a part of near-infrared light. The light emitting device can be used as a light source that has a light emission spectrum similar to that of conventionally used tungsten and xenon lamps and can be downsized compared to tungsten and xenon lamps. A small light emitting device can be mounted on small mobile devices such as smartphones and smartwatches to obtain information in a living body, which can be used to manage physical conditions.

The light emitting device can be used, for example, in a reflection spectroscopic measuring device, and a lighting device capable of non-destructively measuring a living body, fruits and vegetables, and the like, and requiring light excellent in color rendering property.

The second fluorescent material, which has a composition different from that of the first fluorescent material containing the oxide fluorescent material described above, preferably contains at least one fluorescent material selected from the group consisting of a phosphate fluorescent material having a composition represented by the following formula (2a), an aluminate fluorescent material having a composition represented by the following formula (2b), and an aluminate fluorescent material having a composition represented by the following formula (2c); and may contain two or more fluorescent materials of these.

(Ca,Sr,Ba,Mg)₁₀(PO₄)₆(F,Cl,Br,I)₂:Eu (2a)

(Ba,Sr,Ca)MgAl₁₀O₁₇:Eu (2b)

Sr₄Al₁₄O₂₅:Eu (2c)

In the present specification, plural elements sectioned by comma (,) in the composition formulae mean that at least one of these plural elements is contained in the composition.

The third fluorescent material preferably contains at least one fluorescent material selected from the group consisting of a silicate fluorescent material having a composition represented by the following formula (3a), an aluminate fluorescent material or a gallate fluorescent material having a composition represented by the following formula (3b), a β-SiAlON fluorescent material having a composition represented by the following formula (3c), a cesium lead halide fluorescent material having a composition represented by the following formula (3d), and a nitride fluorescent material having a composition represented by the following formula (3e); and may contain two or more fluorescent materials of these. In the case where the third fluorescent material contains two or more fluorescent materials, the two or more third fluorescent materials preferably have light emission peak wavelengths in different ranges within a range of 495 nm or more and less than 610 nm.

(Ca,Sr,Ba)₈MgSi₄O₁₆(F,Cl,Br)₂:Eu (3a)

(Lu,Y,Gd,Tb)₃(Al,Ga)₅O₁₂:Ce (3b)

Si_{6-z}Al_{z}O_{z}N_{8-z}:Eu(0<z≤4.2) (3c)

CsPb(F,Cl,Br)₃ (3d)

(La,Y,Gd)₃Si₆N₁₁:Ce (3e)

The fourth fluorescent material preferably contains at least one fluorescent material selected from the group consisting of a nitride fluorescent material having a composition represented by the following formula (4a), a fluoro-germanate fluorescent material having a composition represented by the following formula (4b), an oxynitride fluorescent material having a composition represented by the following formula (4c), a fluoride fluorescent material having a composition represented by the following formula (4d), a fluoride fluorescent material having a composition represented by the following formula (4e), a nitride fluorescent material having a composition represented by the following formula (4f), and a nitride fluorescent material having a composition represented by the following formula (4g); and may contain two or more fluorescent materials of these. In the case where the fourth fluorescent material contains two or more fluorescent materials, the two or more fourth fluorescent materials preferably have respective light emission peak wavelengths in different ranges within a range of 610 nm or more and less than 700 nm.

(Sr,Ca)AlSiN₃:Eu (4a)

3.5MgO·0.5MgF₂·GeO₂:Mn (4b)

(Ca,Sr,Mg)ₖSi₁₂₋₍ₘ₊ₙ₎Alₘ₊ₙOₙN₁₆₋ₙ:Eu (4c)
wherein k, m, and n satisfy 0<k≤2.0, 2.0≤m≤6.0, and 0≤n≤2.0, respectively.

A¹_{c1}[M⁶_{1-b1}Mn⁴⁺_{b1}F_{d1}] (4d)
wherein A¹ includes at least one selected from the group consisting of K⁺, Li⁺, Na⁺, Rb⁺, Cs⁺, and NH₄⁺, among which K⁺ is preferred; M⁶ includes at least one element selected from the group consisting of Group 4 elements and Group 14 elements, among which Si and Ge are preferred; b1 satisfies 0<b1<0.2; c1 represents the absolute value of the charge of [M⁶_{1-b1}Mn⁴⁺_{b1}F_{d1}] ions; and d1 satisfies 5<d1<7.

A²_{c2}[M⁷_{1-b2}Mn⁴⁺_{b2}F_{d2}] (4e)
wherein A² includes at least one selected from the group consisting of K⁺, Li⁺, Na⁺, Rb⁺, Cs⁺, and NH₄⁺, among which K⁺ is preferred; M⁷ includes a Group 13 element, and may further include at least one element selected from the group consisting of Group 4 elements and Group 14 elements, among which Al is preferred in the Group 13 elements and Si is preferred in the Group 14 elements; b2 satisfies 0<b2<0.2; c2 represents the absolute value of the charge of [M⁷_{1-b2}Mn⁴⁺_{b2}F_{d2}] ions; and d2 satisfies 5<d2<7.

(Ba,Sr,Ca)₂Si₅N₈:Eu (4f)

(Sr,Ca)LiAl₃N₄:Eu (4g)

The fifth fluorescent material preferably contains at least one fluorescent material selected from the group consisting of a gallate fluorescent material having a composition represented by the following formula (5a), an aluminate fluorescent material having a composition represented by the following formula (5b), a gallate fluorescent material having a composition represented by the following formula (5c), an aluminate fluorescent material having a composition represented by the following formula (5d), a fluorescent material having a composition represented by the following formula (5e) different from that of the above oxide fluorescent material, a fluorescent material having a composition represented by the following formula (5f) different from that of the above oxide fluorescent material, a fluorescent material having a composition represented by the following formula (5g) different from that of the above oxide fluorescent material, a fluorescent material having a composition represented by the following formula (5h) different from that of the above oxide fluorescent material, and a fluorescent material having a composition represented by the following formula (5i) different from that of the above oxide fluorescent material; and may contain two or more fluorescent materials of these.

Ga₂O₃:Cr (5a)

Al₂O₃:Cr (5b)

ZnGa₂O₄:Cr (5c)

(Lu,Y,Gd,Tb)₃(Al,Ga)₅O₁₂:Ce,Cr (5d)

M⁸_{g}M⁹ₕM¹⁰ᵢM¹¹₅Oⱼ:Crₑ,M¹²_{f} (5e)
wherein M⁸ represents at least one element selected from the group consisting of Li, Na, Ka, Rb, and Cs; M⁹ represents at least one element selected from the group consisting of Mg, Ca, Sr, Ba, and Zn; M¹⁰ represents at least one element selected from the group consisting of Ba, Al, Ga, In, and rare earth elements; M¹¹ represents at least one element selected from the group consisting of Si, Ti, Ge, Zr, Sn, Hf, and Pb; M¹² represents at least one element selected from the group consisting of Eu, Ce, Tb, Pr, Nd, Sm, Yb, Ho, Er, Tm, Ni, and Mn; and e, f, g, h, i, and j satisfy 0<e≤0.2, 0≤f≤0.1, f<e, 0.7≤g≤1.3, 1.5≤h≤2.5, 0.7≤i≤1.3, and 12.9≤j≤15.1, respectively.

(Mg₁₋ₜ₁M¹³ₜ₁)ᵤ₁(Ga_{1-v1-x1-y1}M¹⁴ᵥ₁)₂O_{w1}:Crₓ₁,M¹⁵_{y1} (5f)
wherein M¹³ represents at least one element selected from the group consisting of Ca, Sr, Ba, Ni, and Zn; M¹⁴ represents at least one element selected from the group consisting of B, Al, Sc, and In; M¹⁵ represents at least one element selected from the group consisting of Eu, Ce, Tb, Pr, Nd, Sm, Yb, Ho, Er, Tm, and Mn; and t1, u1, v1, w1, x1, and y1 satisfy 0≤t1≤0.8, 0.7≤u1≤1.3, 0≤v1≤0.8, 3.7≤w1≤4.3, 0.02<x1≤0.3, 0≤y1≤0.2, and y1<x1, respectively.

(Li₁₋₁₂M¹⁶₁₂)ᵤ₂(Ga₁₋ᵥ₂M¹⁷ᵥ₂)₅O_{w2}:Crₓ₂,Ni_{y2},M¹⁸_{z2} (5g)
wherein M¹⁶ represents at least one element selected from the group consisting of Na, K, Rb, and Cs; M¹⁷ represents at least one element selected from the group consisting of B, Al, Sc, In, and rare earth elements; M¹⁸ represents at least one element selected from the group consisting of Si, Ge, Sn, Ti, Zr, Hf, Bi, V, Nb, and Ta; and t2, u2, v2, w2, x2, y2, and z2 satisfy 0≤t2≤1.0, 0.7≤u2≤1.6, 0≤v2<1.0, 7.85≤w2≤11.5, 0.05≤x2≤1.2, 0≤y2≤0.5, 0.25<x2+y2≤1.2, y2<x2, and 0≤z2≤0.5, respectively.

(Ga₁₋ᵤ₃M¹⁹ᵤ₃)₂(Ge₁₋ᵥ₃M²⁰ᵥ₃)_{w3}Oₓ₃:Cr_{y3},M²¹_{z3} (5h)
wherein M¹⁹ represents at least one element selected from the group consisting of Al, Sc, and In; M²⁰ represents at least one element selected from the group consisting of Si, Ti, Zr, Sn, and Hf; M²¹ represents at least one element selected from the group consisting of Ni, Eu, Fe, Mn, Nd, Tm, Ho, Er, and Yb; and u3, v3, w3, x3, y3, and z3 satisfy 0≤u3≤1.0, 0≤v3≤0.5, 1.0≤w3≤3.0, 5≤x3≤9, 0.005≤y3≤1.0, and 0≤z3≤0.5, respectively.

(Mg₁₋ₛ₄M²²ₛ₄)₂(Al₁₋ₜ₄M²³ₜ₄)ᵤ₄(Ge₁₋ᵥ₄M²⁴ᵥ₄)_{w4}Oₓ₄:Cr_{y4},M²⁵_{z4} (5i)
wherein M²² represents at least one element selected from the group consisting of Ca, Sr, Ba, and Zn; M²³ represents at least one element selected from the group consisting of Ga, Sc, and In; M²⁴ represents at least one element selected from the group consisting of Si, Ti, Zr, Sn, and Hf; M²⁵ represents at least one element selected from the group consisting of Ni, Ce, Eu, Fe, Mn, Nd, Tm, Ho, Er, and Yb; and s4, t4, u4, v4, w4, x4, y4, and z4 satisfy 0≤s4≤1.0, 0≤t4≤1.0, 1.5≤u4≤2.5, 0≤v4≤0.5, 3.0≤w4≤6.0, 11.0≤x4≤17.0, 0.005≤y4≤1.0, and 0≤z4≤0.5, respectively.

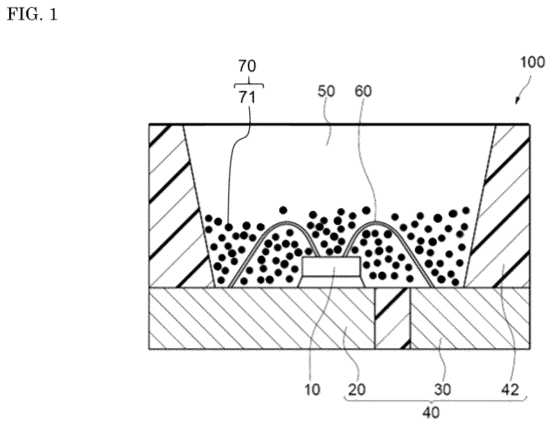

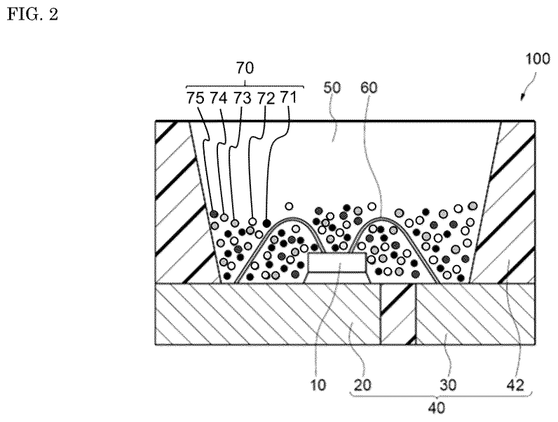

An example of the light emitting device is described with reference to the drawings. FIG. 1 is a schematic cross-sectional view showing an exemplary light emitting device according to a first embodiment of the present disclosure. FIG. 2 is a schematic cross-sectional view showing another exemplary light emitting device according to the first embodiment of the present disclosure.

As shown in FIG. 1, a light emitting device 100 is provided with a molded body 40 having a recessed portion, a light emitting element 10 serving as an excitation light source, and a wavelength conversion member 50 that covers the light emitting element 10. The molded body 40 is formed by integrally molding a first lead 20, a second lead 30, and a resin portion 42 containing a thermoplastic resin or a thermosetting resin. In the molded body 40, at least the first lead 20 and the second lead 30 constitute the bottom surface of the recessed portion, and at least the resin portion 42 constitutes the side surfaces of the recessed portion. The light emitting element 10 is mounted on the bottom surface of the recessed portion of the molded body 40. The light emitting element 10 has a pair of positive and negative electrodes, and the pair of positive and negative electrodes each are electrically connected to the first lead 20 and the second lead 30 via a wire 60. The light emitting element 10 is covered by the wavelength conversion member 50. The wavelength conversion member 50 includes a fluorescent material 70 that converts the wavelength of light emitted from the light emitting element 10, and a light-transmissive material. The fluorescent material 70 necessarily contains a first fluorescent material 71 containing an oxide fluorescent material. The fluorescent material 70 may contain a fluorescent material having a light emission peak wavelength in a wavelength range different from that of the first fluorescent material 71 and having a composition different from that of the first fluorescent material 71. As shown in FIG. 2, the fluorescent material 70 preferably contains at least one fluorescent material selected from the group consisting of the second fluorescent material 72, the third fluorescent material 73, the fourth fluorescent material 74, and the fifth fluorescent material 75 described above, and may contain two or more types of these. The fluorescent material 70 necessarily contains the first fluorescent material 71, and may contain the second fluorescent material 72, the third fluorescent material 73, the fourth fluorescent material 74, and the fifth fluorescent material 75. The wavelength conversion member 50 also functions as a member for protecting, for example, the light emitting element 10, the wire 60, and the fluorescent material 70 from the external environment. The light emitting device 100 emits light by receiving external electric power through the first lead 20 and the second lead 30.

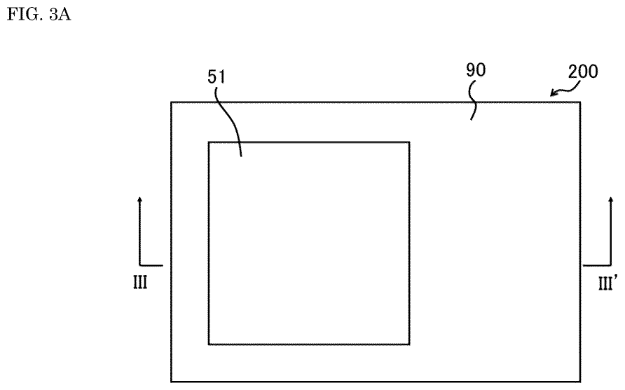

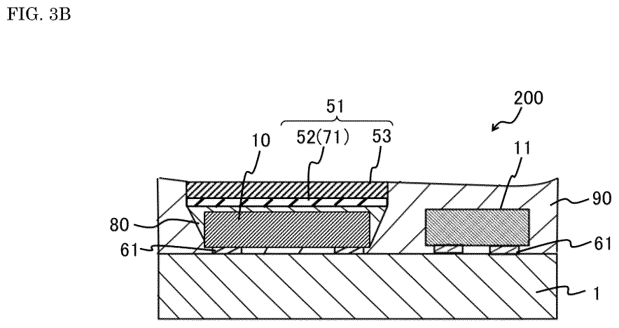

FIGS. 3A and 3B show an exemplary light emitting device according to a second embodiment of the present disclosure. FIG. 3A is a schematic plan view of a light emitting device 200. FIG. 3B is a schematic cross-sectional view of the III-III′ line of the light emitting device 200 shown in FIG. 3A. The light emitting device 200 includes a light emitting element 10 having a light emission peak wavelength of 365 nm or more and 650 nm or less, and a wavelength conversion member 51 including a wavelength conversion body 52 containing a first fluorescent material 71 that is excited by light emitted from the light emitting element 10 and emits light, and a light-transmissive body 53 on which the wavelength conversion body 52 is arranged. The light emitting element 10 is flip-chip mounted on a substrate 1 via bumps that are conductive members 61. The wavelength conversion body 52 of the wavelength conversion member 51 is arranged on the light emitting surface of the light emitting element 10 via an adhesive layer 80. The side surfaces of the light emitting element 10 and the wavelength conversion member 51 are covered with a covering member 90 that reflects light. The wavelength conversion body 52 is excited by light emitted from the light emitting element 10 and necessarily contains the first fluorescent material 71 containing an oxide fluorescent material. The wavelength conversion body 52 may contain at least one selected from the group consisting of the second fluorescent material, the third fluorescent material, the fourth fluorescent material, and the fifth fluorescent material. The light emitting element 10 receives electric power from the outside of the light emitting device 200 via the wiring and the conductive members 61 formed on the substrate 1, thereby enabling the light emitting device 200 to emit light. The light emitting device 200 may include a semiconductor element 11 such as a protective element for preventing the light emitting element 10 from being destroyed due to excessive voltage application. The semiconductor element 11 may be mounted on the substrate 1 via the conductive members 61. The covering member 90 is arranged so as to cover, for example, the semiconductor element 11. Each member used in the light emitting device is described below. For the details, for example, the disclosure of Japanese Unexamined Patent Publication No. 2014-112635 may be referred to.

Examples of the light-transmissive material constituting the wavelength conversion body together with the fluorescent material include at least one selected from the group consisting of resin, glass, and inorganic substances. The resin can use at least one resin selected from the group consisting of a silicone resin, an epoxy resin, a phenol resin, a polycarbonate resin, an acrylic resin, and modified resins thereof. Among them, a silicone resin and a modified silicone resin are preferred because of their excellent heat and light resistance. The wavelength conversion member may optionally contain a filler, a colorant, and a light diffusing material in addition to the fluorescent material and the light-transmissive material. Examples of the filler include silicon oxide, barium titanate, titanium oxide, and aluminum oxide.

The light-transmissive body can use a plate-shaped body made of a light-transmissive material such as glass or resin. Examples of the glass include borosilicate glass and quartz glass. Examples of the resin include a silicone resin and an epoxy resin. When the wavelength conversion member includes a substrate, the substrate is preferably made of an insulating material that is difficult to transmit light from the light emitting element and external light. Examples of the material of the substrate include ceramics such as aluminum oxide and aluminum nitride, and resins such as a phenol resin, an epoxy resin, a polyimide resin, a bismaleimide triazine resin (BT resin), and a polyphthalamide (PPA) resin. When an adhesive layer is interposed between the light emitting element and the wavelength conversion member, the adhesive constituting the adhesive layer is preferably made of a material capable of optically connecting the light emitting element and the wavelength conversion member. The material constituting the adhesive layer is preferably at least one resin selected from the group consisting of an epoxy resin, a silicone resin, a phenol resin, and a polyimide resin. The light-transmissive body need not be arranged on the wavelength conversion member.

Examples of the semiconductor element optionally arranged in the light emitting device include a transistor for controlling the light emitting element and a protective element for suppressing the destruction and the performance deterioration of the light emitting element due to excessive voltage application. Examples of the protective element include a Zener diode. When the light emitting device includes a covering member, it is preferable to use an insulating material as the material of the covering member. More specific examples thereof include a phenol resin, an epoxy resin, a bismaleimide triazine resin (BT resin), a polyphthalamide (PPA) resin, and a silicone resin. A colorant, a fluorescent material, and a filler may be optionally added to the covering member. The light emitting device may use bumps as conductive members. Examples of the material of the bumps include Au and an alloy thereof, and examples of the other conductive member include eutectic solder (Au—Sn), Pb—Sn, and lead-free solder.

An example of the method for producing an exemplary light emitting device according to the first embodiment is described below. For the details, for example, the disclosure of Japanese Unexamined Patent Publication No. 2010-062272 may be referred to. The method for producing a light emitting device preferably includes a step of preparing a molded body, a step of arranging a light emitting element, a step of arranging a wavelength conversion member-forming composition, and a step of forming a resin package. When using an aggregated molded body having a plurality of recessed portions as the molded body, the production method may include an individualizing step of separating each resin package in each unit region after the step of forming a resin package.

In the step of preparing a molded body, a plurality of leads are integrally molded using a thermosetting resin or a thermoplastic resin to prepare a molded body having a recessed portion with side surfaces and a bottom surface. The molded body may be formed from an aggregated substrate including a plurality of recessed portions.

In the step of arranging a light emitting element, a light emitting element is arranged on the bottom surface of the recessed portion of the molded body, and the positive and negative electrodes of the light emitting element are connected to the first lead and the second lead, respectively, by a wire.

In the step of arranging a wavelength conversion member-forming composition, a wavelength conversion member-forming composition is arranged in the recessed portion of the molded body.

In the step of forming a resin package, the wavelength conversion member-forming composition arranged in the recessed portion of the molded body is cured to form a resin package, thereby producing a light emitting device. When using a molded body formed from an aggregated substrate having a plurality of recessed portions, in the individualizing step after the step of forming a resin package, the resin package is separated for each resin package in each unit region of the aggregated substrate having a plurality of recessed portions, thereby producing individual light emitting devices. As described above, the light emitting devices shown in FIGS. 1 and 2 can be produced.

An example of the method for producing an exemplary light emitting device according to the second embodiment is described below. For the details, for example, the disclosure of Japanese Unexamined Patent Publication No. 2014-112635 or Japanese Unexamined Patent Publication No. 2017-117912 may be referred to. The method for producing a light emitting device preferably includes a step of arranging a light emitting element, optionally a step of arranging a semiconductor element, a step of forming a wavelength conversion member including a wavelength conversion body, a step of adhering a light emitting element and a wavelength conversion member, and a step of forming a covering member.

For example, in the step of arranging a light emitting element, a light emitting element is arranged on a substrate. The light emitting element and a semiconductor element are flip-chip mounted, for example, on the substrate. Next, in the step of forming a wavelength conversion member including a wavelength conversion body, a wavelength conversion body may be obtained by forming a plate-shaped, sheet-shaped, or layered wavelength conversion body on one surface of a light-transmissive body by a printing method, an adhesive method, a compression molding method, or an electrodeposition method. For example, in the printing method, the composition for a wavelength conversion body containing a fluorescent material and a resin serving as a binder or a solvent can be printed on one surface of the light-transmissive body to form a wavelength converter member including a wavelength conversion body. Next, in the step of adhering a light emitting element and a wavelength conversion member, the wavelength conversion member is opposed to the light emitting surface of the light emitting element, and the wavelength conversion member is adhered onto the light emitting element by an adhesive layer. Next, in the step of forming a covering member, the side surfaces of the light emitting element and the wavelength conversion member are covered with the composition for a covering member. The covering member is for reflecting light emitted from the light emitting element, and when the light emitting device also includes a semiconductor element, it is preferable to form the covering member such that the semiconductor element is embedded by the covering member. As described above, the light emitting device shown in FIGS. 3A and 3B can be produced.

The method for producing an oxide fluorescent material includes: preparing a first compound containing Mg and/or a second compound containing at least one first element M¹ selected from the group consisting of Ca, Sr, Ba, and Zn, a third compound containing Li and/or a fourth compound containing at least one second element M² selected from the group consisting of Na, K, Rb, and Cs, a fifth compound containing In, a seventh compound containing Ge and/or an eighth compound containing at least one fourth element M⁴ selected from the group consisting of Si, Ti, Zr, Sn, and Hf, a ninth compound containing Cr, optionally a sixth compound containing at least one third element M³ selected from the group consisting of Al, Ga, and Sc, and optionally a tenth compound containing at least one fifth element M⁵ selected from the group consisting of Ni, Ce, Eu, Fe, Mn, Nd, Tm, Ho, Er, and Yb; adjusting and mixing the first compound and/or the second compound, the third compound and/or the fourth compound, the fifth compound, the seventh compound and/or the eighth compound, the ninth compound, optionally the sixth compound, and optionally the tenth compound to prepare a raw material mixture such that, when the total molar ratio of Mg and/or the at least one first element M¹ in 1 mol of the composition of the oxide fluorescent material is the parameter q, the molar ratio of the at least one first element M¹ is a product of the parameter p and the parameter q, the parameter p is a numerical value of 0 or more and 1.0 or less, the parameter q is a numerical value of 0.1 or more and 0.9 or less, and the molar ratio of Mg is a product of 1 minus the parameter p and the parameter q, when the total molar ratio of Li and/or the at least one second element M² is the parameter s, the molar ratio of the at least one second element M² is a product of the parameter r and the parameter s, the parameter r is a numerical value of 0 or more and 1.0 or less, the parameter s is a numerical value of 0.05 or more and 0.45 or less, and the molar ratio of Li is a product of 1 minus the parameter r and the parameter s, when the total molar ratio of In and the at least one third element M³ is the parameter u, the molar ratio of the at least one third element M³ is a product of the parameter t and the parameter u, the parameter t is a numerical value of 0 or more and 0.5 or less, the parameter u is a numerical value of 0.05 or more and 0.45 or less, and the molar ratio of In is a product of 1 minus the parameter t and the parameter u, and when the total molar ratio of Ge and/or the at least one fourth element M⁴ is the parameter w, the molar ratio of the at least one fourth element M⁴ is a product of the parameter v and the parameter w, the parameter v is a numerical value of 0 or more and 1.0 or less, the parameter w is a numerical value of 0.8 or more and 1.3 or less, the molar ratio of Ge is a product of 1 minus the parameter v and the parameter w, the total molar ratio of the parameter q, the parameter s, and the parameter u is a numerical value of 0.9 or more and 1.2 or less, the molar ratio of Cr is the parameter y, the parameter y is a numerical value of 0.002 or more and 0.5 or less, the molar ratio of the at least one fifth element M⁵ is the parameter z, and the parameter z is a numerical value of 0 or more and 0.3 or less; and heat-treating the raw material mixture at a temperature of 800° C. or higher and 1,400° C. or lower in an atmosphere containing oxygen to obtain an oxide fluorescent material, wherein at least one selected from the group consisting of the first compound, the second compound, the third compound, the fourth compound, the fifth compound, the seventh compound, the eighth compound, and the ninth compound preferably uses an oxide. The oxide fluorescent material to be obtained preferably has a molar ratio of each element of the oxide fluorescent material in the same range as the charged composition for obtaining the raw material mixture in 1 mol of the composition of the oxide fluorescent material.

The raw materials for producing an oxide fluorescent material include a first compound containing Mg and/or a second compound containing the first element M¹, a third compound containing Li and/or a fourth compound containing the second element M², a fifth compound containing In, a seventh compound containing Ge and/or an eighth compound containing the fourth element M⁴, and a ninth compound containing Cr, and may include a sixth compound containing the third element M³ included as necessary, and a tenth compound containing the fifth element M⁵ included as necessary. The raw materials for producing an oxide fluorescent material may include at least one compound selected from the group consisting of a first compound containing Mg and a second compound containing the first element M¹. The raw materials for producing an oxide fluorescent material may include at least one compound selected from the group consisting of a third compound containing Li and a fourth compound containing the second element M². The raw materials for producing an oxide fluorescent material may include at least one compound selected from the group consisting of a seventh compound containing Ge and an eighth compound containing the fourth element M⁴. Examples of the first compound, the second compound, the third compound, the fourth compound, the fifth compound, the sixth compound, the seventh compound, the eighth compound, the ninth compound, and the tenth compound include oxides, carbonates, and chlorides, and hydrates of these, respectively. At least one compound selected from the group consisting of the first compound, the second compound, the third compound, the fourth compound, the fifth compound, the seventh compound, the eighth compound, and the ninth compound is an oxide, and two or more compounds may be oxides. The sixth compound containing the third element M³ included as necessary or the tenth compound containing the fifth element M⁵ included as necessary may be an oxide. The first compound, the second compound, the third compound, the fourth compound, the fifth compound, the seventh compound, the eighth compound, and the ninth compound are preferably in the form of powder. The sixth compound and the tenth compound may be in the form of powder.

Examples of the first compound containing Mg include MgO, MgCO₃, and MgCl₂. Examples of the second compound containing the first element M¹ include CaO, CaCO₃, CaCl₂), SrO, SrCO₃, SrCl₂, BaO, BaCO₃, BaCl₂, ZnO, ZnCO₃, and ZnCl₂. Examples of the third compound containing Li include Li₂O, LiCl, and Li₂CO₃. Examples of the fourth compound containing the second element M² include Na₂O, NaCl, Na₂CO₃, K₂O, KCl, K₂CO₃, Rb₂O, RbCl, Rb₂CO₃, Cs₂O, CsCl, and Cs₂CO₃. Examples of the fifth compound containing In include In₂O₃ and InCl₃. Examples of the seventh compound containing Ge include GeO₂ and GeCl₄. Examples of the eighth compound containing the fourth element M⁴ include SiO₂, TiO₂, TiCl₄, ZrO₂, ZrCl₄, SnO₂, SnCl₂, HfO₂, and HfCl₄. Examples of the ninth compound containing Cr include Cr₂O₃, Cr₂(CO₃)₃, and CrCl₃. The first compound, the second compound, the third compound, the fourth compound, the fifth compound, the seventh compound, the eighth compound, and the ninth compound may be hydrates.

Examples of the sixth compound containing the third element M³ include Al₂O₃, AlCl₃, Ga₂O₃, GaCl₃, SC₂O₃, and ScCl₃. The sixth compound may be a hydrate.

Examples of the tenth compound containing the fifth element M⁵ include NiO, NiCl₂, CeO₂, CeCl₃, Ce₂(CO₃)₃, Eu₂O₃, EuCl₃, Fe₂O₃, Fe₃O₄, FeCl₂, FeCl₃, FeCO₃, Fe₂(CO₃)₃, MnO, MnO₂, Mn₂O₃, Mn₃O₄, Nd₂(CO₃)₃, Nd₂O₃, NdCl₃, Tm₂O₃, TmCl₃, Ho₂O₃, HoCl₃, Er₂O₃, ErCl₃, Yb₂O₃, and YbCl₃.

### The Tenth Compound May be a Hydrate.

The raw material mixture is preferably prepared by adjusting and mixing raw materials so as to have a composition represented by the following formula (1). The oxide fluorescent material obtained by the production method preferably has a composition in which each element of the oxide fluorescent material is the same as the composition represented by the following formula (1) for obtaining the raw material mixture in 1 mol of the composition of the oxide fluorescent material.

(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Oₓ:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p<1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2.

In the raw material mixture, in the composition represented by the formula (1), a part of Mg may be replaced by the at least one first element M¹; or Mg may entirely be replaced by Zn of the first elements M¹, by two or more first elements M¹ that are Ca and at least one selected from the group consisting of Sr, Ba, and Zn, or by two or more first elements M¹ that are Zn and at least one selected from the group consisting of Ca, Sr, and Ba. In the raw material mixture, in the composition of the oxide fluorescent material represented by the formula (1), a part of Li may be replaced by at least one second element M²; or Li may entirely be replaced by at least one second element M² or by Na of the second element M². In the raw material mixture, in the composition represented by the formula (1), a part of In may be replaced by at least one third element M³. In the raw material mixture, in the composition represented by the formula (1), a part of Ge may be replaced by the at least one fourth element M⁴; or Ge may entirely be replaced by at least one fourth element M⁴ or by Si of the fourth element M⁴.

In the composition represented by the formula (1), the raw material mixture is preferably mixed with the ninth compound containing Cr such that y satisfies 0.020≤y≤0.070. In the composition represented by the formula (1), the raw material mixture is preferably mixed with the fifth compound containing In and the sixth compound containing the third element M³ included as necessary such that u satisfies 0.25≤u≤0.40. In the composition represented by the formula (1), the raw material mixture is preferably mixed with the second compound containing the first element M¹ such that p satisfies 0≤p<1.0. In the composition represented by the formula (1), the raw material mixture may be mixed with the first compound containing Mg and the second compound containing the first element M¹ such that p satisfies 0≤p≤0.4 and q satisfies 0.6≤q≤0.9. In the composition represented by the formula (1), the raw material mixture may be mixed with the first compound containing Mg and/or the second compound containing the first element M¹ such that q satisfies 0.5≤q≤0.9. In the composition represented by the formula (1), the raw material mixture may be mixed with the seventh compound containing Ge and the eighth compound containing the fourth element M⁴ such that v satisfies 0≤v<0.5. In one example, no eighth compound containing the fourth element M⁴ is mixed into the raw material mixture such that v satisfies v=0 in the composition represented by the formula (1). In one example, no fourth compound containing the second element M² is mixed into the raw material mixture such that such that r satisfies r=0 in the composition represented by the formula (1).

The first compound and/or the second compound, the third compound and/or the fourth compound, the fifth compound, the seventh compound and/or the eighth compound, the ninth compound, the sixth compound included as necessary, and the tenth compound included as necessary, which are weighed such that the elements contained in each compound of the raw material satisfy the aforementioned composition, can be mixed in wet or in dry to obtain a raw material mixture. The weighed compounds may be mixed using a mixing machine. As the mixing machine, for example, a ball mill, a vibration mill, a roll mill, and a jet mill, which are industrially commonly used, can be used.

The raw material mixture may contain a flux. When the raw material mixture contains a flux, the reaction between the raw materials is promoted more and the solid-phase reaction proceeds more uniformly, so that a fluorescent material having a large particle diameter and excellent light emission characteristics can be obtained. When the temperature of the heat treatment for obtaining a fluorescent material is similar to the temperature at which the liquid phase of the compound used as the flux is formed, the flux promotes the reaction between the raw materials. As a flux, boric acid, a borate containing at least one element selected from the group consisting of alkaline earth metal elements and alkali metal elements, or a halide containing at least one element selected from the group consisting of alkaline earth metal elements and alkali metal elements can be used. Among the halides, fluoride can be used as a flux. For example, boric acid (H₃BO₃) and lithium fluoride (LiF) can be used as fluxes.

The raw material mixture can be placed in a crucible or a boat made of a material such as graphite or other carbon, boron nitride (BN), alumina (Al₂O₃), tungsten (W), or molybdenum (Mo), and heat-treated in a furnace.

The raw material mixture is heat-treated in an atmosphere containing oxygen. The content of oxygen in the atmosphere is not particularly limited. The content of oxygen in the atmosphere containing oxygen is preferably 5% by volume or more, more preferably 10% by volume or more, and even more preferably 15% by volume or more. The heat treatment is preferably performed in an air atmosphere (oxygen content of 20% by volume or more). When the atmosphere does not contain oxygen, such as an oxygen content of less than 1% by volume, an oxide fluorescent material having a desired composition may not be obtained.

The temperature at which the raw material mixture is heat-treated is 800° C. or higher and 1,400° C. or lower, preferably 850° C. or higher and 1,300° C. or lower, more preferably 870° C. or higher and 1,290° C. or lower, and even more preferably 900° C. or higher and 1,280° C. or lower. When the heat treatment temperature is 800° C. or higher and 1,400° C. or lower, decomposition due to heat is suppressed, and a fluorescent material having a desired composition and a stable crystal structure can be obtained.

In the heat treatment, a maintaining time at a predetermined temperature may be set up. The maintaining time may be, for example, 0.5 hour or more and 48 hours or less, may be 1 hour or more and 40 hours or less, may be 2 hours or more and 30 hours or less, may be 3 hours or more and 20 hours or less, and may be 5 hours or more and 10 hours or less. By setting the maintaining time in the range of 0.5 hour or more and 48 hours or less, the crystal growth can be promoted.

The pressure in the heat treatment atmosphere may be standard atmospheric pressure (0.101 MPa, air atmosphere), and may be 0.101 MPa or more; and the heat treatment may be performed in a pressurized atmosphere range of 0.11 MPa or more and 200 MPa or less. In the heat-treated product to be obtained by the heat treatment, the crystal structure is more easily decomposed at a higher heat treatment temperature, but in a pressurized atmosphere, the decomposition of the crystal structure can be suppressed.

The heat treatment time can be appropriately selected depending on the heat treatment temperature and the pressure of the atmosphere during the heat treatment, and is preferably 0.5 hour or more and 20 hours or less. Even in the case of performing two or more stages of heat treatment, the time for one heat treatment is preferably 0.5 hour or more and 20 hours or less. When the heat treatment time is 0.5 hour or more and 20 hours or less, the decomposition of the heat-treated product to be obtained is suppressed, and a fluorescent material having a stable crystal structure and a desired light emission intensity can be obtained. In addition, the production cost can be reduced and the production time can be relatively shortened. The heat treatment time is more preferably 1 hour or more and 10 hours or less, and even more preferably 1.5 hours or more and 9 hours or less.

The heat-treated product obtained by the heat treatment may be subjected to post-treatments such as pulverization, dispersion, solid-liquid separation, and drying. The solid-liquid separation may be performed by a method generally used industrially, such as filtration, suction filtration, pressure filtration, centrifugal separation, and decantation. The drying may be performed with an apparatus generally used industrially, such as a vacuum dryer, a hot air dryer, a conical dryer, and a rotary evaporator.

### EXAMPLES

The present disclosure is hereunder specifically described by reference to the following Examples. The present disclosure is not limited to the following Examples.

### Oxide Fluorescent Material

### Example 1

For raw materials, 2.90 g of a first compound MgO, 0.33 g of a third compound Li₂CO₃, 1.25 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.8}Li_{0.1}In_{0.1}Ge₁O₃:Cr_{0.026} in the charged composition. Using an agate mortar and an agate pestle, the raw materials were mixed for 10 minutes to obtain a raw material mixture. The resulting raw material mixture was placed in an alumina crucible and heat-treated at 1220° C. for 8 hours in an air atmosphere (20% by volume of oxygen) with standard air pressure (0.101 MPa). After the heat treatment, the resulting heat-treated product was pulverized to obtain an oxide fluorescent material of Example 1 having the composition shown in Table 1, which has the molar ratios in the charged composition. In the composition of the oxide fluorescent material of Example 1 shown in Table 1, the parameter p in the formula (1) is 0 (p=0), the parameter q is 0.8 (q=0.8), the parameter r is 0 (r=0), the parameter s is 0.1 (s=0.1), the parameter t is 0 (t=0), the parameter u is 0.1 (u=0.1), the parameter v is 0 (v=0), the parameter w is 1.0 (w=1.0), the parameter x is 3.0 (x=3.0), the parameter y is 0.026 (y=0.026), and the parameter z is 0 (z=0). In the compositional formula, there may be elements without numerical values, and the molar ratio of elements without numerical values is 1.

### Example 2

For raw materials, 2.18 g of a first compound MgO, 0.66 g of a third compound Li₂CO₃, 2.50 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.6}Li_{0.2}In_{0.2}Ge₁O₃:Cr_{0.026} in the charged composition. The other procedures were the same as in Example 1 to obtain an oxide fluorescent material of Example 2 having the composition shown in Table 1, which has the molar ratios in the charged composition. In the composition of the oxide fluorescent material of Example 2 shown in Table 1, the parameter p in the formula (1) is 0 (p=0), the parameter q is 0.6 (q=0.6), the parameter r is 0 (r=0), the parameter s is 0.2 (s=0.2), the parameter tis 0 (t=0), the parameter u is 0.2 (u=0.2), the parameter v is 0 (v=0), the parameter w is 1.0 (w=1.0), the parameter x is 3.0 (x=3.0), the parameter y is 0.026 (y=0.026), and the parameter z is 0 (z=0).

### Example 3

For raw materials, 1.82 g of a first compound MgO, 0.83 g of a third compound Li₂CO₃, 3.13 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.5}Li_{0.25}In_{0.25}Ge₁O₃:Cr_{0.026} in the charged composition. The other procedures were the same as in Example 1 to obtain an oxide fluorescent material of Example 3 having the composition shown in Table 1, which has the molar ratios in the charged composition. In the composition of the oxide fluorescent material of Example 3 shown in Table 1, the parameter p in the formula (1) is 0 (p=0), the parameter q is 0.5 (q=0.5), the parameter r is 0 (r=0), the parameter s is 0.25 (s=0.25), the parameter tis 0 (t=0), the parameter u is 0.25 (u=0.25), the parameter v is 0 (v=0), the parameter w is 1.0 (w=1.0), the parameter x is 3.0 (x=3.0), the parameter y is 0.026 (y=0.026), and the parameter z is 0 (z=0).

### Example 4

For raw materials, 1.46 g of a first compound MgO, 1.00 g of a third compound Li₂CO₃, 3.76 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.4}Li_{0.3}In_{0.3}Ge₁O₃:Cr_{0.026} in the charged composition. The other procedures were the same as in Example 1 to obtain an oxide fluorescent material of Example 4 having the composition shown in Table 1, which has the molar ratios in the charged composition. In the composition of the oxide fluorescent material of Example 4 shown in Table 1, the parameter p in the formula (1) is 0 (p=0), the parameter q is 0.4 (q=0.4), the parameter r is 0 (r=0), the parameter s is 0.3 (s=0.3), the parameter tis 0 (t=0), the parameter u is 0.3 (u=0.3), the parameter v is 0 (v=0), the parameter w is 1.0 (w=1.0), the parameter x is 3.0 (x=3.0), the parameter y is 0.026 (y=0.026), and the parameter z is 0 (z=0).

### Example 5

For raw materials, 0.73 g of a first compound MgO, 1.33 g of a third compound Li₂CO₃, 5.01 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.2}Li_{0.4}In_{0.4}Ge₁O₃:Cr_{0.026} in the charged composition. The other procedures were the same as in Example 1 to obtain an oxide fluorescent material of Example 5 having the composition shown in Table 1, which has the molar ratios in the charged composition. In the composition of the oxide fluorescent material of Example 5 shown in Table 1, the parameter p in the formula (1) is 0 (p=0), the parameter q is 0.2 (q=0.2), the parameter r is 0 (r=0), the parameter s is 0.4 (s=0.4), the parameter t is 0 (t=0), the parameter u is 0.4 (u=0.4), the parameter v is 0 (v=0), the parameter w is 1.0 (w=1.0), the parameter x is 3.0 (x=3.0), the parameter y is 0.026 (y=0.026), and the parameter z is 0 (z=0).

### Example 6

For raw materials, 0.36 g of a first compound MgO, 1.50 g of a third compound Li₂CO₃, 5.63 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.1}Li_{0.45}In_{0.45}Ge₁O₃:Cr_{0.026} in the charged composition. The other procedures were the same as in Example 1 to obtain an oxide fluorescent material of Example 6 having the composition shown in Table 1, which has the molar ratios in the charged composition. In the composition of the oxide fluorescent material of Example 6 shown in Table 1, the parameter p in the formula (1) is 0 (p=0), the parameter q is 0.1 (q=0.1), the parameter r is 0 (r=0), the parameter s is 0.45 (s=0.45), the parameter t is 0 (t=0), the parameter u is 0.45 (u=0.45), the parameter v is 0 (v=0), the parameter w is 1.0 (w=1.0), the parameter x is 3.0 (x=3.0), the parameter y is 0.026 (y=0.026), and the parameter z is 0 (z=0).

### Example 7

For raw materials, 1.82 g of a first compound MgO, 0.83 g of a third compound Li₂CO₃, 3.13 g of a fifth compound In₂O₃, 9.41 g of a seventh compound GeO₂, and 0.30 g of a ninth compound Cr₂O₃ were weighed and used. The raw materials were weighed such that the molar ratio of each element in 1 mol of the composition of the oxide fluorescent material to be obtained was Mg_{0.5}Li_{0.25}In_{0.25}Ge₁O₃:Cr_{0.044} in the charged composition. The other procedures were the same as in Example 1 to obtain an oxide fluorescent material of Example 7 having the composition shown in Table 1, which has the molar ratios in the charged composition. In the composition of the oxide fluorescent material of Example 7 shown in Table 1, the parameter p in the formula (1) is 0 (p=0), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 0 (v=0), the parameter w is 1.0 (w=1.0), the parameter x is 3.0 (x=3.0), the parameter y is 0.044 (y=0.044), and the parameter z is 0 (z=0).

### Example 8

For raw materials, 2.18 g of a first compound MgO, 0.66 g of a third compound Li₂CO₃, 2.50 g of a fifth compound In₂O₃, 9.41 g of a seventh compound GeO₂, and 0.36 g of a ninth compound Cr₂O₃ were weighed and used. The raw materials were weighed such that the molar ratio of each element in 1 mol of the composition of the oxide fluorescent material to be obtained was Mg_{0.6}Li_{0.2}In_{0.2}Ge₁O₃:Cr_{0.052} in the charged composition. The other procedures were the same as in Example 1 to obtain an oxide fluorescent material of Example 8 having the composition shown in Table 1, which has the molar ratios in the charged composition. In the composition of the oxide fluorescent material of Example 8 shown in Table 1, the parameter p in the formula (1) is 0 (p=0), the parameter q is 0.6 (q=0.6), the parameter r is 0 (r=0), the parameter s is 0.2 (s=0.2), the parameter t is 0 (t=0), the parameter u is 0.2 (u=0.2), the parameter v is 0 (v=0), the parameter w is 1.0 (w=1.0), the parameter x is 3.0 (x=3.0), the parameter y is 0.052 (y=0.052), and the parameter z is 0 (z=0).

### Example 9

For raw materials, 2.18 g of a first compound MgO, 0.66 g of a third compound Li₂CO₃, 2.50 g of a fifth compound In₂O₃, 9.41 g of a seventh compound GeO₂, and 0.45 g of a ninth compound Cr₂O₃ were weighed and used. The raw materials were weighed such that the molar ratio of each element in 1 mol of the composition of the oxide fluorescent material to be obtained was Mg_{0.6}Li_{0.2}In_{0.2}Ge₁O₃:Cr_{0.065} in the charged composition. The other procedures were the same as in Example 1 to obtain an oxide fluorescent material of Example 9 having the composition shown in Table 1, which has the molar ratios in the charged composition. In the composition of the oxide fluorescent material of Example 9 shown in Table 1, the parameter p in the formula (1) is 0 (p=0), the parameter q is 0.6 (q=0.6), the parameter r is 0 (r=0), the parameter s is 0.2 (s=0.2), the parameter tis 0 (t=0), the parameter u is 0.2 (u=0.2), the parameter v is 0 (v=0), the parameter w is 1.0 (w=1.0), the parameter x is 3.0 (x=3.0), the parameter y is 0.065 (y=0.065), and the parameter z is 0 (z=0).

### Example 10

For raw materials, 3.66 g of ZnO, which is a second compound containing Zn as the first element M¹, 0.83 g of a third compound Li₂CO₃, 3.13 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Zn_{0.5}Li_{0.25}In_{0.25}Ge₁O₃:Cr_{0.026} in the charged composition. An oxide fluorescent material of Example 10 having the composition shown in Table 1, which has the molar ratios in the charged composition, was obtained in the same manner as in Example 1 except that the heat treatment temperature was 1,100° C. In the composition of the oxide fluorescent material of Example 10 shown in Table 1, the element M¹ in the formula (1) is Zn, the parameter p is 1 (p=1), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 0 (v=0), the parameter w is 1.0 (w=1.0), the parameter x is 3.0 (x=3.0), the parameter y is 0.026 (y=0.026), and the parameter z is 0 (z=0).

### Example 11

For raw materials, 1.82 g of a first compound MgO, 1.19 g of Na₂CO₃, which is a fourth compound containing Na as the second element M², 3.13 g of a fifth compound In₂O₃, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg_{0.5}Na_{0.25}In_{0.25}Ge₁O₃:Cr_{0.026} in the charged composition. The other procedures were the same as in Example 1 to obtain an oxide fluorescent material of Example 11 having the composition shown in Table 1, which has the molar ratios in the charged composition. In the composition of the oxide fluorescent material of Example 11 shown in Table 1, the element M² in the formula (1) is Na, the parameter p is 0 (p=0), the parameter q is 0.5 (q=0.5), the parameter r is 1.0 (r=1.0), the parameter s is 0.25 (s=0.25), the parameter t is 0 (t=0), the parameter u is 0.25 (u=0.25), the parameter v is 0 (v=0), the parameter w is 1.0 (w=1.0), the parameter x is 3.0 (x=3.0), the parameter y is 0.026 (y=0.026), and the parameter z is 0 (z=0).

### Example 12

For raw materials, 1.82 g of a first compound MgO, 0.83 g of a third compound Li₂CO₃, 3.13 g of a fifth compound In₂O₃, 5.41 g of SiO₂, which is an eighth compound containing Si as the fourth element M⁴, and 0.18 g of a ninth compound Cr₂O₃ were weighed and used. The raw materials were weighed such that the molar ratio of each element in 1 mol of the composition of the oxide fluorescent material to be obtained was Mg_{0.5}Li_{0.25}In_{0.25}Si₁O₃:Cr_{0.026} in the charged composition. An oxide fluorescent material of Example 12 having the composition shown in Table 1, which has the molar ratios in the charged composition, was obtained in the same manner as in Example 1 except that the heat treatment temperature was 1,270° C. In the composition of the oxide fluorescent material of Example 12 shown in Table 1, the element M⁴ in the formula (1) is Si, the parameter p is 0 (p=0), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 1.0 (v=1.0), the parameter w is 1.0 (w=1.0), the parameter x is 3.0 (x=3.0), the parameter y is 0.026 (y=0.026), and the parameter z is 0 (z=0).

### Example 13

For raw materials, 1.82 g of a first compound MgO, 0.83 g of a third compound Li₂CO₃, 3.13 g of a fifth compound In₂O₃, 7.06 g of a seventh compound GeO₂, 1.36 g of SiO₂, which is an eighth compound containing Si as the fourth element M⁴, and 0.18 g of a ninth compound Cr₂O₃ were weighed and used.

The raw materials were weighed such that the molar ratio of each element in 1 mol of the composition of the oxide fluorescent material to be obtained was Mg_{0.5}Li_{0.25}In_{0.25}Ge_{0.75}Si_{0.25}O₃:Cr_{0.026} in the charged composition. The other procedures were the same as in Example 1 to obtain an oxide fluorescent material of Example 13 having the composition shown in Table 1, which has the molar ratios in the charged composition. In the composition of the oxide fluorescent material of Example 13 shown in Table 1, the element M⁴ in the formula (1) is Si, the parameter p is 0 (p=0), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 0.25 (v=0.25), the parameter w is 1.0 (w=1.0), the parameter x is 3.0 (x=3.0), the parameter y is 0.026 (y=0.026), and the parameter z is 0 (z=0).

### Example 14

For raw materials, 1.27 g of a first compound MgO, 1.10 g of ZnO, which is a second compound containing Zn as the first element M¹, 0.83 g of a third compound Li₂CO₃, 3.13 g of a fifth compound In₂O₃, 9.41 g of a seventh compound GeO₂, and 0.18 g of a ninth compound Cr₂O₃ were weighed and used.

The raw materials were weighed such that the molar ratio of each element in 1 mol of the composition of the oxide fluorescent material to be obtained was Mg_{0.35}Zn_{0.15}Li_{0.25}In_{0.25}Ge₁O₃:Cr_{0.026} in the charged composition. An oxide fluorescent material of Example 14 having the composition shown in Table 1, which has the molar ratios in the charged composition, was obtained in the same manner as in Example 1 except that the heat treatment temperature was 1,200° C. In the composition of the oxide fluorescent material of Example 14 shown in Table 1, the element M¹ in the formula (1) is Zn, the parameter p is 0.3 (p=0.3), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 0 (v=0), the parameter w is 1.0 (w=1.0), the parameter x is 3.0 (x=3.0), the parameter y is 0.026 (y=0.026), and the parameter z is 0 (z=0).

### Example 15

For raw materials, 1.27 g of a first compound MgO, 1.35 g of CaCO₃, which is a second compound containing Ca as the first element M¹, 0.83 g of a third compound Li₂CO₃, 3.13 g of a fifth compound In₂O₃, 9.41 g of a seventh compound GeO₂, and 0.18 g of a ninth compound Cr₂O₃ were weighed and used.

The raw materials were weighed such that the molar ratio of each element in 1 mol of the composition of the oxide fluorescent material to be obtained was Mg_{0.35}Ca_{0.15}Li_{0.25}In_{0.25}Ge₁O₃:Cr_{0.026} in the charged composition. An oxide fluorescent material of Example 15 having the composition shown in Table 1, which has the molar ratios in the charged composition, was obtained in the same manner as in Example 1 except that the heat treatment temperature was 1,200° C. In the composition of the oxide fluorescent material of Example 15 shown in Table 1, the element M¹ in the formula (1) is Ca, the parameter p is 0.3 (p=0.3), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 0 (v=0), the parameter w is 1.0 (w=1.0), the parameter x is 3.0 (x=3.0), the parameter y is 0.026 (y=0.026), and the parameter z is 0 (z=0).

### Example 16

For raw materials, 1.27 g of a first compound MgO, 1.99 g of SrCO₃, which is a second compound containing Sr as the first element M¹, 0.83 g of a third compound Li₂CO₃, 3.13 g of a fifth compound In₂O₃, 9.41 g of a seventh compound GeO₂, and 0.18 g of a ninth compound Cr₂O₃ were weighed and used.

The raw materials were weighed such that the molar ratio of each element in 1 mol of the composition of the oxide fluorescent material to be obtained was Mg_{0.35}Sr_{0.15}Li_{0.25}In_{0.25}Ge₁O₃:Cr_{0.026} in the charged composition. The other procedures were the same as in Example 1 to obtain an oxide fluorescent material of Example 16 having the composition shown in Table 1, which has the molar ratios in the charged composition. In the composition of the oxide fluorescent material of Example 16 shown in Table 1, the element M¹ in the formula (1) is Sr, the parameter p is 0.3 (p=0.3), the parameter q is 0.5 (q=0.5), the parameter r is 0 (r=0), the parameter s is 0.25 (s=0.25), the parameter t is 0 (t=0), the parameter u is 0.25 (u=0.25), the parameter v is 0 (v=0), the parameter w is 1.0 (w=1.0), the parameter x is 3.0 (x=3.0), the parameter y is 0.026 (y=0.026), and the parameter z is 0 (z=0).

### Comparative Example 1

For raw materials, 3.63 g of a first compound MgO, 9.41 g of a seventh compound GeO₂, and 0.18 g of a ninth compound Cr₂O₃ were weighed and used. The raw materials were weighed such that the molar ratio of each element in 1 mol of the composition of the oxide fluorescent material to be obtained was Mg₁Ge₁O₃:Cr_{0.026} in the charged composition. The other procedures were the same as in Example 1 to obtain an oxide fluorescent material of Comparative Example 1 having the composition shown in Table 1, which has the molar ratios in the charged composition. The oxide fluorescent material of Comparative Example 1 does not contain Li and/or the second element M² nor In in 1 mol of the composition, and thus does not have the composition represented by the formula (1).

### Measurement of Light Emission Spectrum and Light Emission Characteristics

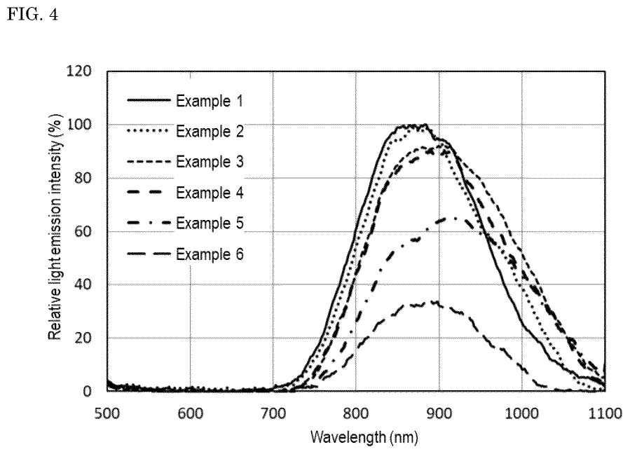

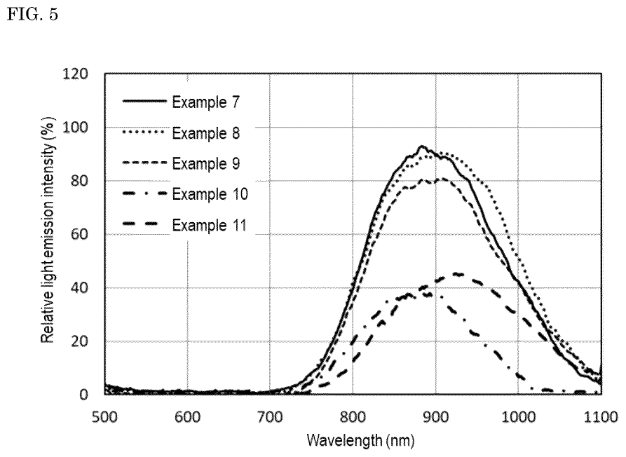

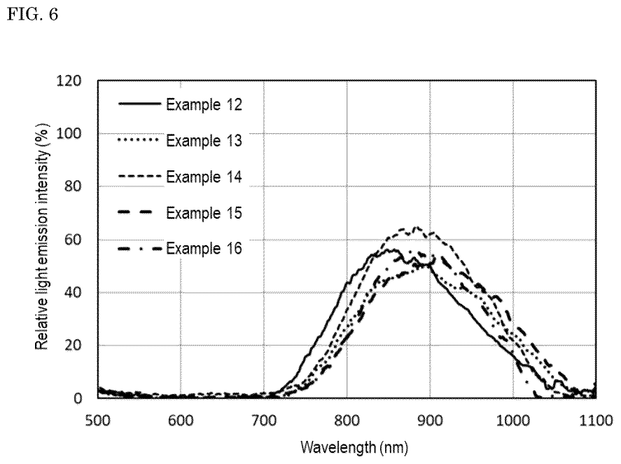

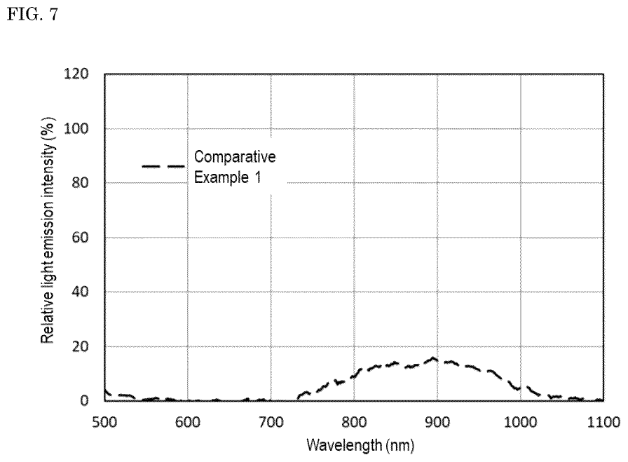

For the oxide fluorescent material in each of Examples and Comparative Example, the light emission spectrum was measured using a quantum efficiency measurement system (QE-2000, manufactured by Otsuka Electronics Co., Ltd.). The light emission peak wavelength of the excitation light of the light emitting element, which is a semiconductor element, used in the quantum efficiency measurement system was 450 nm. From the obtained light emission spectrum of each fluorescent material, the relative light emission intensity, light emission peak wavelength, and full width at half maximum were determined as light emission characteristics. Specifically, the light emission peak wavelength (nm) in the light emission spectrum of each fluorescent material and the full width at half maximum (FWHM) (nm) of the light emission spectrum of the light emission peak wavelength were determined. Furthermore, in the light emission spectrum of each oxide fluorescent material, the light emission intensity (%) at 1,000 nm was determined relative to 100% of the light emission intensity of the light emission peak wavelength. The light emission intensity of the oxide fluorescent material according to Example 1 was defined as 100%, and the light emission intensity of the oxide fluorescent material according to each of Examples and Comparative Example other than Example 1 was determined as the relative light emission intensity (%). The results are shown in Table 1. FIGS. 4 to 6 show the light emission spectra of the oxide fluorescent materials according to Examples 1 to 16, and FIG. 7 shows the light emission spectrum of the oxide fluorescent material according to Comparative Example 1.

TABLE 1

| | | | | | Light emission |
|---|---|---|---|---|---|
| | | | | | intensity at |
| | | Light | Full | Relative | 1,000 nm relative |
| | | emission | width | light | to light |
| | | peak | at half | emission | emission peak |
| | | wavelength | maximum | intensity | wavelength |
| | | (nm) | (nm) | (%) | (%) |
| Example 1 | Mg_{0.8}Li_{0.1}In_{0.1}Ge₁O₃:Cr_{0.026} | 883 | 175 | 100 | 25.6 |
| Example 2 | Mg_{0.6}Li_{0.2}In_{0.2}Ge₁O₃:Cr_{0.026} | 886 | 185 | 99 | 39.1 |
| Example 3 | Mg_{0.5}Li_{0.25}In_{0.25}Ge₁O₃:Cr_{0.026} | 899 | 206 | 102 | 55.9 |
| Example 4 | Mg_{0.4}Li_{0.3}In_{0.3}Ge₁O₃:Cr_{0.026} | 888 | 198 | 97 | 50.2 |
| Example 5 | Mg_{0.2}Li_{0.4}In_{0.4}Ge₁O₃:Cr_{0.026} | 914 | 214 | 74 | 65.5 |
| Example 6 | Mg_{0.1}Li_{0.45}In_{0.45}Ge₁O₃:Cr_{0.026} | 889 | 162 | 30 | 24.7 |
| Example 7 | Mg_{0.5}Li_{0.25}In_{0.25}Ge₁O₃:Cr_{0.044} | 883 | 183 | 96 | 45.6 |
| Example 8 | Mg_{0.6}Li_{0.2}In_{0.2}Ge₁O₃:Cr_{0.052} | 908 | 204 | 101 | 56.4 |
| Example 9 | Mg_{0.6}Li_{0.2}In_{0.2}Ge₁O₃:Cr_{0.065} | 909 | 197 | 87 | 51.9 |
| Example 10 | Zn_{0.5}Li_{0.25}In_{0.25}Ge₁O₃:Cr_{0.026} | 885 | 160 | 35 | 18.2 |
| Example 11 | Mg_{0.5}Na_{0.25}In_{0.25}Ge₁O₃:Cr_{0.026} | 924 | 202 | 48 | 66.6 |
| Example 12 | Mg_{0.5}Li_{0.25}In_{0.25}Si₁O₃:Cr_{0.026} | 857 | 184 | 58 | 28.6 |
| Example 13 | Mg_{0.5}Li_{0.25}In_{0.25}Ge_{0.75}Si_{0.25}O₃:Cr_{0.026} | 893 | 199 | 53 | 48.2 |
| Example 14 | Mg_{0.35}Zn_{0.15}Li_{0.25}In_{0.25}Ge₁O₃:Cr_{0.026} | 884 | 182 | 64 | 33.4 |
| Example 15 | Mg_{0.35}Ca_{0.15}Li_{0.25}In_{0.25}Ge₁O₃:Cr_{0.026} | 907 | 195 | 56 | 53.0 |
| Example 16 | Mg_{0.35}Sr_{0.15}Li_{0.25}In_{0.25}Ge₁O₃:Cr_{0.026} | 885 | 168 | 51 | 31.2 |
| Comparative | Mg₁Ge₁O₃:Cr_{0.026} | 895 | 189 | 15 | 29.8 |
| Example 1 | | | | | |

As shown in Table 1 and FIGS. 4 to 6, the oxide fluorescent material according to each of Examples 1 to 16 emitted light having a light emission peak wavelength in the range of 830 nm or more and 930 nm or less in the light emission spectrum, and having a light emission intensity required for analysis in the wavelength range from red light to near-infrared light, more specifically in the wavelength range of near-infrared light.

The oxide fluorescent material according to each of Examples 1 to 9 contained Mg, Li, In, Ge, and Cr in 1 mol of the composition of the oxide fluorescent material, and did not contain the first element M¹, the second element M², the third element M³, the fourth element M⁴, and the fifth element M⁵. The oxide fluorescent material according to each of Examples 1 to 9 had a parameter y representing the molar ratio of Cr as an activating element in the formula (1) in the range of 0.020 or more and 0.070 or less (0.020≤y≤0.070) in 1 mol of the composition, and had a light emission spectrum with a light emission peak wavelength in the longer wavelength range of 880 nm or more and 930 nm or less in the wavelength range of near-infrared light and with a wider full width at half maximum of 160 nm or more and 220 nm or less. The oxide fluorescent material according to each of Examples 3 to 5 and 7 had a parameter u representing the total molar ratio of In and the third element M³ in the formula (1) (the total molar ratio of In and the third element M³ is the parameter u representing the molar ratio of In, since the third element M³ is not contained) in the range of 0.25 or more and 0.40 or less (0.25≤u≤0.40) in 1 mol of the composition, and had a light emission spectrum with a relatively wider full width at half maximum in the range of 180 nm or more and 220 nm or less and with a light emission intensity at 1,000 nm of 45% or more relative to 100% of the light emission intensity of the light emission peak wavelength, thereby emitting light having a light emission intensity required for analysis in the wavelength range of near-infrared light.

The oxide fluorescent material according to Example 10 had all of Mg replaced by Zn as the first element M¹ in 1 mol of the composition of the oxide fluorescent material, and thus had a light emission peak wavelength in the longer wavelength range of 880 nm or more and 930 nm or less in the wavelength range of near-infrared light and a wider full width at half maximum of 160 nm or more and 220 nm or less.

The oxide fluorescent material according to Example 11 had all of Li replaced by Na as the second element M² in 1 mol of the composition of the oxide fluorescent material, and thus had a light emission peak wavelength in the longer wavelength range of 920 nm or more and 930 nm or less in the wavelength range of near-infrared light and a wider full width at half maximum of 200 nm or more and 220 nm or less, thereby having a high light emission intensity at 1,000 nm of 65% or more relative to 100% of the light emission intensity of the light emission peak wavelength.

In the oxide fluorescent material according to each of Examples 12 and 13, an entirety or a part of Ge may be replaced by Si as the fourth element M⁴ in 1 mol of the composition of the oxide fluorescent material. The oxide fluorescent material thus had a light emission peak wavelength in the longer wavelength range of 850 nm or more and 930 nm or less in the wavelength range of near-infrared light and a wider full width at half maximum of 180 nm or more and 220 nm or less, thereby having a light emission intensity at 1,000 nm of 25% or more relative to 100% of the light emission intensity of the light emission peak wavelength.

In the oxide fluorescent material according to each of Examples 14 to 16, a part of Mg is replaced by at least one element selected from the group consisting of Zn, Ca, and Sr as the first element M¹ in 1 mol of the composition of the oxide fluorescent material, and the parameter p in the formula (1) was in the range of 0 or more and 0.4 or less (0≤p≤0.4) and the parameter q was in the range of 0.6 or more and 0.9 or less (0.6≤q≤0.9). The oxide fluorescent material according to each of Examples 14 to 16 had a light emission peak wavelength in the longer wavelength range of 880 nm or more and 930 nm or less in the wavelength range of near-infrared light and a wider full width at half maximum of 160 nm or more and 220 nm or less, thereby having a light emission intensity at 1,000 nm of 30% or more relative to 100% of the light emission intensity of the light emission peak wavelength.

The oxide fluorescent material according to Comparative Example 1 did not contain Li and/or the second element M² and In in 1 mol of the composition of the oxide fluorescent material, and did not have the composition represented by the formula (1). The oxide fluorescent material according to Comparative Example 1 had a low relative light emission intensity of 15%.

Embodiments according to the present disclosure include the following oxide fluorescent material and the light emitting device using the same. Embodiments according to the present disclosure preferably include the following method for producing an oxide fluorescent material.

[Aspect 1] An oxide fluorescent material, having a composition represented by the following formula (1):

(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p≤1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2.

[Aspect 2] The oxide fluorescent material according to Aspect 1, wherein y satisfies 0.020≤y≤0.070 in the formula (1).

[Aspect 3] The oxide fluorescent material according to Aspect 1 or 2, wherein u satisfies 0.25≤u≤0.40 in the formula (1).

[Aspect 4] The oxide fluorescent material according to any one of Aspects 1 to 3, wherein p satisfies 0≤p<1.0 in the formula (1).

[Aspect 5] The oxide fluorescent material according to any one of Aspects 1 to 4, wherein v satisfies 0≤v<0.5 in the formula (1).

[Aspect 6] The oxide fluorescent material according to Aspect 4, wherein v satisfies v=0 in the formula (1).

[Aspect 7] The oxide fluorescent material according to Aspect 6, wherein r satisfies r=0 in the formula (1).

[Aspect 8] The oxide fluorescent material according to any one of Aspects 1 to 3, wherein p and q satisfy 0≤p<0.4 and 0.6≤q≤0.9, respectively, in the formula (1).

[Aspect 9] The oxide fluorescent material according to any one of Aspects 1 to 3, wherein q satisfies 0.5≤q≤0.9 in the formula (1).

[Aspect 10] The oxide fluorescent material according to any one of Aspects 1 to 9, having a light emission spectrum with a full width at half maximum of a light emission peak wavelength that is 150 nm or more and 220 nm or less.

[Aspect 11] The oxide fluorescent material according to Aspect 6 or 7, having a light emission spectrum with a full width at half maximum of a light emission peak wavelength that is 175 nm or more and 220 nm or less.

[Aspect 12] The oxide fluorescent material according to any one of Aspects 1 to 11, having a light emission spectrum with a light emission peak wavelength that is 830 nm or more and 930 nm or less.

[Aspect 13] The oxide fluorescent material according to Aspect 6 or 7, having a light emission spectrum with a light emission peak wavelength that is 870 nm or more and 930 nm or less.

[Aspect 14] The oxide fluorescent material according to Aspect 8, having a light emission spectrum with a light emission peak wavelength that is 860 nm or more and 930 nm or less.

[Aspect 15] The oxide fluorescent material according to Aspect 9, having a light emission spectrum with a light emission peak wavelength that is 860 nm or more and 930 nm or less.

[Aspect 16] The oxide fluorescent material according to any one of Aspects 2 to 5, having a light emission spectrum with a light emission intensity at 1,000 nm that is 37% or more relative to the light emission intensity at the light emission peak wavelength as 100%.

[Aspect 17] A light emitting device, including the oxide fluorescent material according to any one of Aspects 1 to 16 and a light emitting element having a light emission peak wavelength of 365 nm or more and 650 nm or less and irradiating the oxide fluorescent material.

[Aspect 18] A method for producing an oxide fluorescent material including:
preparing a first compound containing Mg and/or a second compound containing a first element M¹, a third compound containing Li and/or a fourth compound containing a second element M², a fifth compound containing In, a seventh compound containing Ge and/or an eighth compound containing a fourth element M⁴, a ninth compound containing Cr, optionally a sixth compound containing a third element M³, and optionally a tenth compound containing a fifth element M⁵;
adjusting and mixing the first compound and/or the second compound, the third compound and/or the fourth compound, the fifth compound, the seventh compound and/or the eighth compound, the ninth compound, optionally the sixth compound, and optionally the tenth compound to prepare a raw material mixture such that, when the total molar ratio of Mg and/or the first element M¹ in 1 mol of the composition of the oxide fluorescent material is the parameter q, the molar ratio of the first element M¹ is a product of the parameter p and the parameter q, the parameter p is a numerical value of 0 or more and 1.0 or less, the parameter q is a numerical value of 0.1 or more and 0.9 or less, and the molar ratio of Mg is a product of 1 minus the parameter p and the parameter q, when the total molar ratio of Li and/or the second element M² is the parameter s, the molar ratio of the second element M² is a product of the parameter r and the parameter s, the parameter r is a numerical value of 0 or more and 1.0 or less, the parameter s is a numerical value of 0.05 or more and 0.45 or less, and the molar ratio of Li is a product of 1 minus the parameter r and the parameter s, when the total molar ratio of In and the third element M³ is the parameter u, the molar ratio of the third element M³ is a product of the parameter t and the parameter u, the parameter t is a numerical value of 0 or more and 0.5 or less, the parameter u is a numerical value of 0.05 or more and 0.45 or less, and the molar ratio of In is a product of 1 minus the parameter t and the parameter u, and when the total molar ratio of Ge and/or the fourth element M⁴ is the parameter w, the molar ratio of the fourth element M⁴ is a product of the parameter v and the parameter w, the parameter v is a numerical value of 0 or more and 1.0 or less, the parameter w is a numerical value of 0.8 or more and 1.3 or less, the molar ratio of Ge is a product of 1 minus the parameter v and the parameter w, the total molar ratio of the parameter q, the parameter s, and the parameter u is a numerical value of 0.9 or more and 1.2 or less, the molar ratio of Cr is the parameter y, the parameter y is a numerical value of 0.002 or more and 0.5 or less, the molar ratio of the fifth element M⁵ is the parameter z, and the parameter z is a numerical value of 0 or more and 0.3 or less; and heat-treating the raw material mixture at a temperature of 800° C. or higher and 1,400° C. or lower in an atmosphere containing oxygen to obtain an oxide fluorescent material.

[Aspect 19] The method for producing an oxide fluorescent material according to Aspect 18, including adjusting and mixing the raw materials such that the raw material mixture has a composition represented by the following formula (1):

(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p≤1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2, respectively.

The oxide fluorescent material according to the present disclosure can be used in light emitting devices for medical use to obtain information inside living bodies, light emitting devices to be mounted on small mobile devices such as smartphones and smartwatches to manage physical conditions, light emitting devices used in medical devices, light emitting devices for analyzers to non-destructively measure the internal information of agricultural products such as fruits and vegetables and rice, foods, and pharmaceutical products, light emitting devices for plant cultivation to affect the photoreceptors of plants, and light emitting devices for reflection spectroscopic measuring devices used for measuring film thickness.

What is claimed is:

1. An oxide fluorescent material, having a composition represented by the following formula (1):
(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf, M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p≤1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2.

2. The oxide fluorescent material according to claim 1, wherein y satisfies 0.020≤y≤0.070 in the formula (1).

3. The oxide fluorescent material according to claim 1, wherein u satisfies 0.25≤u≤0.40 in the formula (1).

4. The oxide fluorescent material according to claim 1, wherein p satisfies 0≤p<1.0 in the formula (1).

5. The oxide fluorescent material according to claim 1, wherein v satisfies 0≤v≤0.5 in the formula (1).

6. The oxide fluorescent material according to claim 4, wherein v satisfies v=0 in the formula (1).

7. The oxide fluorescent material according to claim 6, wherein r satisfies r=0 in the formula (1).

8. The oxide fluorescent material according to claim 1, wherein p and q satisfy 0≤p<0.4 and 0.6≤q≤0.9, respectively, in the formula (1).

9. The oxide fluorescent material according to claim 1, wherein q satisfies 0.5≤q≤0.9 in the formula (1).

10. The oxide fluorescent material according to claim 1, having a light emission spectrum with a full width at half maximum of a light emission peak wavelength that is 150 nm or more and 220 nm or less.

11. The oxide fluorescent material according to claim 6, having a light emission spectrum with a full width at half maximum of a light emission peak wavelength that is 175 nm or more and 220 nm or less.

12. The oxide fluorescent material according to claim 1, having a light emission peak wavelength that is 830 nm or more and 930 nm or less.

13. The oxide fluorescent material according to claim 6, having a light emission peak wavelength that is 870 nm or more and 930 nm or less.

14. The oxide fluorescent material according to claim 8, having a light emission peak wavelength that is 860 nm or more and 930 nm or less.

15. The oxide fluorescent material according to claim 9, having a light emission peak wavelength that is 860 nm or more and 930 nm or less.

16. The oxide fluorescent material according to claim 2, having a light emission spectrum with a light emission intensity at 1,000 nm that is 37% or more relative to the light emission intensity at the light emission peak wavelength as 100%.

17. A light emitting device, comprising:
the oxide fluorescent material according to claim 1; and
a light emitting element irradiating the oxide fluorescent material and having a light emission peak wavelength that is 365 nm or more and 650 nm or less.

18. A method for producing an oxide fluorescent material including:
preparing a raw material mixture comprising a first compound containing Mg and/or a second compound containing a first element M¹, a third compound containing Li and/or a fourth compound containing a second element M², a fifth compound containing In, a seventh compound containing Ge and/or an eighth compound containing a fourth element M⁴, a ninth compound containing Cr, optionally a sixth compound containing a third element M³, and optionally a tenth compound containing a fifth element M⁵;
wherein the raw material mixture has a composition in which when the total molar ratio of Mg and/or the first element M¹ in 1 mol of the oxide fluorescent material is a parameter q, a molar ratio of the first element M¹ is a product of the parameter p and a parameter q, the parameter p is a numerical value of 0 or more and 1.0 or less, the parameter q is a numerical value of 0.1 or more and 0.9 or less, and a molar ratio of Mg is a product of 1 minus the parameter p and the parameter q, when a total molar ratio of Li and/or the second element M² is the parameter s, a molar ratio of the second element M² is a product of a parameter r and a parameter s, the parameter r is a numerical value of 0 or more and 1.0 or less, the parameter s is a numerical value of 0.05 or more and 0.45 or less, and a molar ratio of Li is a product of 1 minus the parameter r and the parameter s, when the total molar ratio of In and the third element M³ is a parameter u, a molar ratio of the third element M³ is a product of a parameter t and a parameter u, the parameter t is a numerical value of 0 or more and 0.5 or less, the parameter u is a numerical value of 0.05 or more and 0.45 or less, and a molar ratio of In is a product of 1 minus the parameter t and the parameter u, and when a total molar ratio of Ge and/or the fourth element M⁴ is a parameter w, a molar ratio of the fourth element M⁴ is a product of a parameter v and a parameter w, the parameter v is a numerical value of 0 or more and 1.0 or less, the parameter w is a numerical value of 0.8 or more and 1.3 or less, a molar ratio of Ge is a product of 1 minus the parameter v and the parameter w, a total molar ratio of the parameter q, the parameter s, and the parameter u is a numerical value of 0.9 or more and 1.2 or less, a molar ratio of Cr is a parameter y, the parameter y is a numerical value of 0.002 or more and 0.5 or less, a molar ratio of the fifth element M⁵ is a parameter z, and the parameter z is a numerical value of 0 or more and 0.3 or less; and
heat-treating the raw material mixture at a temperature of 800° C. or higher and 1,400° C. or lower in an atmosphere containing oxygen to obtain the oxide fluorescent material.

19. The method for producing an oxide fluorescent material according to claim 18,
wherein the raw material mixture has a composition represented by the following formula (1):
(Mg₁₋ₚM¹ₚ)_{q}(Li₁₋ᵣM²ᵣ)ₛ(In₁₋ₜM³ₜ)ᵤ(Ge₁₋ᵥM⁴ᵥ)_{w}Ox:Cr_{y},M⁵_{z} (1)
wherein M¹ represents at least one element selected from the group consisting of Ca, Sr, Ba, and Zn; M² represents at least one element selected from the group consisting of Na, K, Rb, and Cs; M³ represents at least one element selected from the group consisting of Al, Ga, and Sc; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; and p, q, r, s, t, u, v, w, x, y, and z satisfy 0≤p<1.0, 0.1≤q≤0.9, 0≤r≤1.0, 0.05≤s≤0.45, 0≤t≤0.5, 0.05≤u≤0.45, 0≤v≤1.0, 0.8≤w≤1.3, 2.6≤x≤3.6, 0.002≤y≤0.5, 0≤z≤0.3, and 0.9≤q+s+u≤1.2, respectively.
